(19) United States
(12) Patent Application Publication
(10) Pub. No.: US 2020/0402958 A1
(43) Pub. Date: Dec. 24, 2020

(54) SEMICONDUCTOR DEVICE PACKAGES AND METHODS OF MANUFACTURING THE SAME

(71) Applicant: Advanced Semiconductor Engineering, Inc., Kaohsiung (TW)

(72) Inventors: Hsu-Nan FANG, Kaohsiung (TW); Chen Yuan WENG, Kaohsiung (TW)

(73) Assignee: Advanced Semiconductor Engineering, Inc., Kaohsiung (TW)

(21) Appl. No.: 16/447,805

(22) Filed: Jun. 20, 2019

(51) Int. Cl. H01L 25/065; H01L 25/00; H01L 21/56; H01L 23/00; H01L 25/18

(52) U.S. Cl. CPC H01L 25/0657; H01L 25/50; H01L 21/561; H01L 24/16; H01L 25/18; H01L 2224/16145; H01L 2225/06513; H01L 2225/06555; H01L 2224/16057; H01L 2224/16012; H01L 2225/06586

(57) ABSTRACT

A semiconductor device package includes a redistribution layer, a first semiconductor device, a second semiconductor device, a first insulation body, and a second insulation body. The first semiconductor device can be disposed on the redistribution layer. The second semiconductor device can be stacked on the first semiconductor device. The first insulation body can be disposed between the first semiconductor device and the second semiconductor device. The first insulation body may have a number of first particles. The second insulation body can encapsulate the first insulation body and have a number of second particles. One of the number of first particles can have a flat surface.

### BACKGROUND

### 1. Field of the Disclosure

The present disclosure relates to, amongst other things, semiconductor device packages and methods of manufacturing the same.

### 2. Description of Related Art

A semiconductor device package may include some semiconductor devices stacked to one another on a substrate, however, it may consume relatively great time in stacking the semiconductor devices onto the substrate.

### SUMMARY

According to some example embodiments of the instant disclosure, a semiconductor device package includes a redistribution layer, a first semiconductor device, a second semiconductor device, a first insulation body, and a second insulation body. The first semiconductor device can be disposed on the redistribution layer. The second semiconductor device can be stacked on the first semiconductor device. The first insulation body can be disposed between the first semiconductor device and the second semiconductor device. The first insulation body may have a number of first particles. The second insulation body can encapsulate the first insulation body and have a number of second particles. One of the number of first particles can have a flat surface.

According to some example embodiments of the instant disclosure, a semiconductor device package includes a redistribution layer, a first semiconductor device, a second semiconductor device, a first insulation body, and a second insulation body. The first semiconductor device can be disposed on the redistribution layer. The first semiconductor device may have a first lateral surface. The second semiconductor device can be stacked on the first semiconductor device. The second semiconductor device may have a first lateral surface. The first insulation body can be disposed between the first semiconductor device and the second semiconductor device. The first insulation body may have a first lateral surface. The second insulation body can encapsulate the first insulation body. The first lateral surface of the first insulation body can be substantially coplanar with the first lateral surface of the second semiconductor device.

According to some example embodiments of the instant disclosure, a method of manufacturing a semiconductor device package includes providing a wafer including a number of first semiconductor devices; forming a number of stacks of second semiconductor devices on the wafer; and encapsulating the number of stacks of second semiconductor devices and the wafer by a first insulation material.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A is a cross-sectional view of a semiconductor device package in accordance with some embodiments of the present disclosure.

FIG. 1B is a cross-sectional view of another semiconductor device package in accordance with some embodiments of the present disclosure.

FIG. 1C is a cross-sectional view of another semiconductor device package in accordance with some embodiments of the present disclosure.

FIG. 1D is an enlarged view of structure in dotted circle A as shown in FIG. 1A.

FIG. 1E is an enlarged view of structure in dotted box B as shown in FIG. 1A.

FIG. 2A, FIG. 2B, FIG. 2C, FIG. 2D, FIG. 2E, FIG. 2F, FIG. 2G, FIG. 2H, FIG. 2I and FIG. 2J illustrate various stages of a method for manufacturing a semiconductor device package accordance with some embodiments of the subject application.

FIG. 2A, FIG. 2B, FIG. 2C, FIG. 2D, FIG. 2K, FIG. 2L, FIG. 2M, FIG. 2N, FIG. 2O and FIG. 2P illustrate various stages of another method for manufacturing a semiconductor device package accordance with some embodiments of the subject application.

FIG. 2A, FIG. 2B, FIG. 2Q, FIG. 2R, FIG. 2S, FIG. 2T, FIG. 2U, FIG. 2V, and FIG. 2W illustrate various stages of another method for manufacturing a semiconductor device package accordance with some embodiments of the subject application.

FIG. 3A is a cross-sectional view of another semiconductor device package in accordance with some embodiments of the present disclosure.

FIG. 3B is a cross-sectional view of another semiconductor device package in accordance with some embodiments of the present disclosure.

FIG. 3C is a cross-sectional view of another semiconductor device package in accordance with some embodiments of the present disclosure.

FIG. 3D is a cross-sectional view of another semiconductor device package in accordance with some embodiments of the present disclosure.

FIG. 3E is a cross-sectional view of another semiconductor device package in accordance with some embodiments of the present disclosure.

FIG. 3F is a cross-sectional view of another semiconductor device package in accordance with some embodiments of the present disclosure.

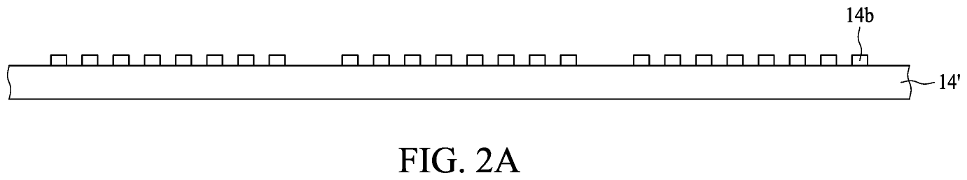

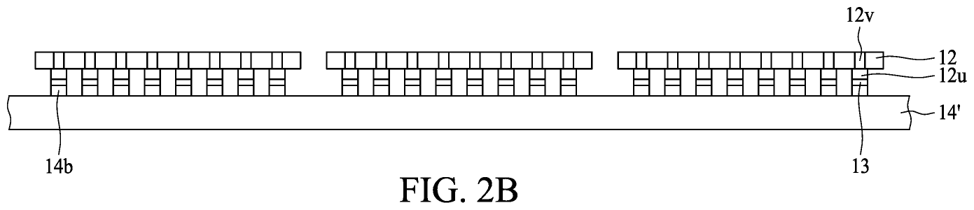

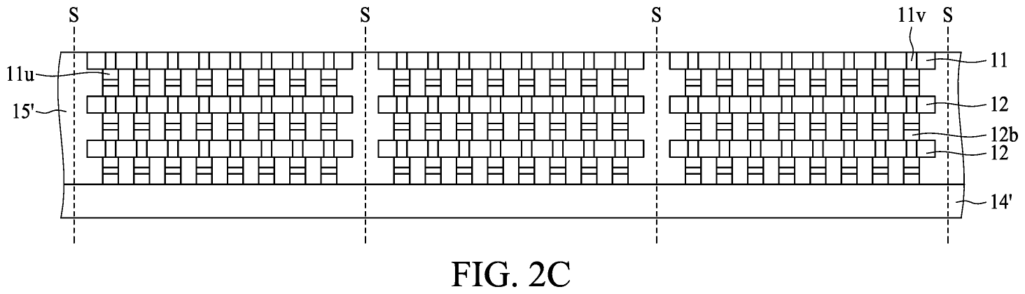

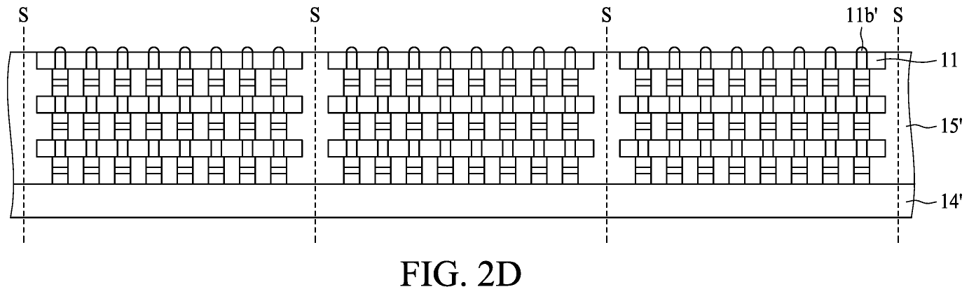

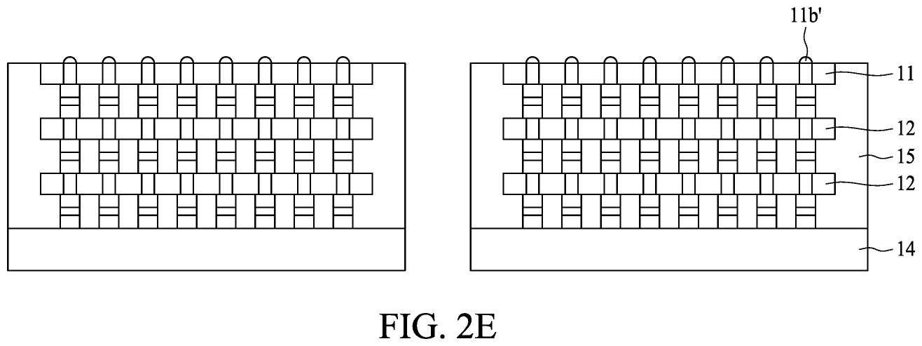

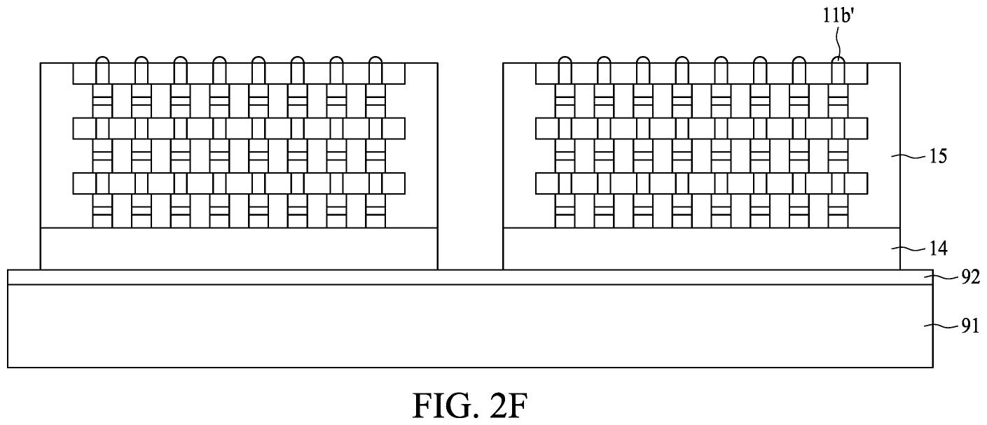

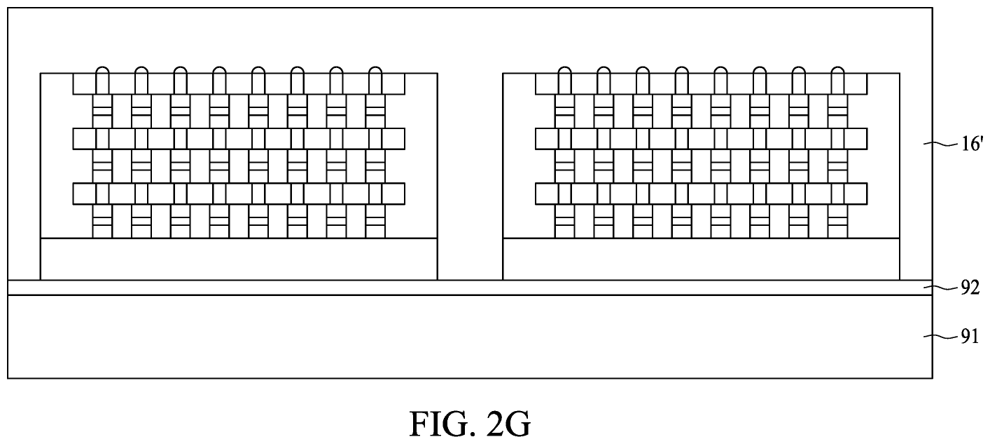

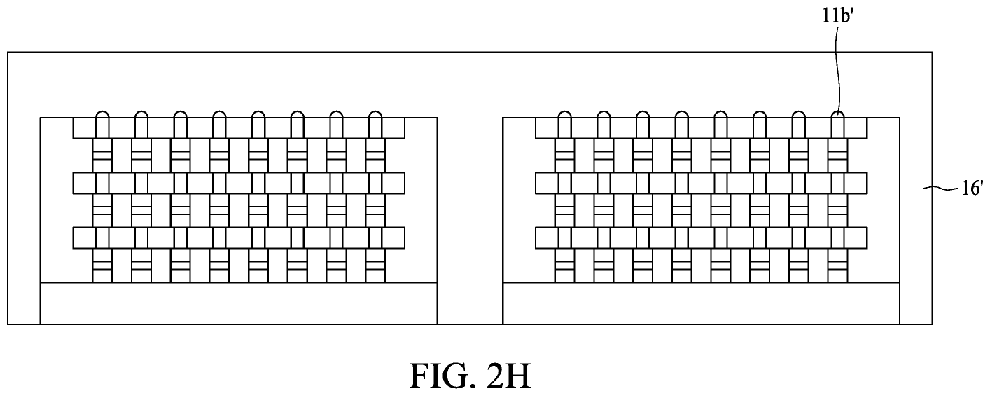

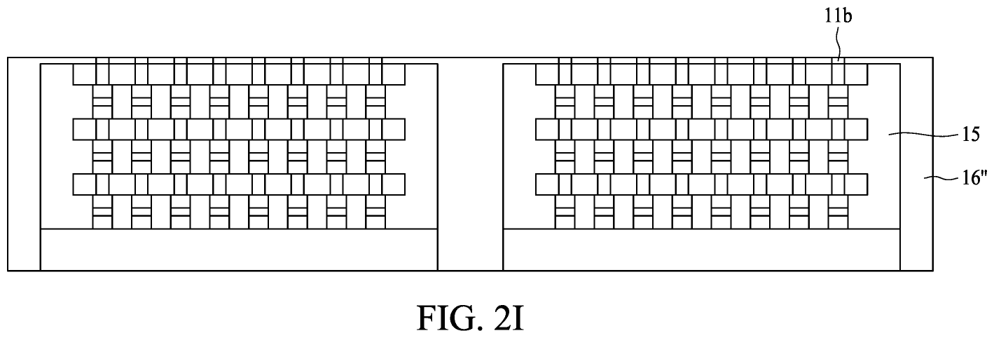

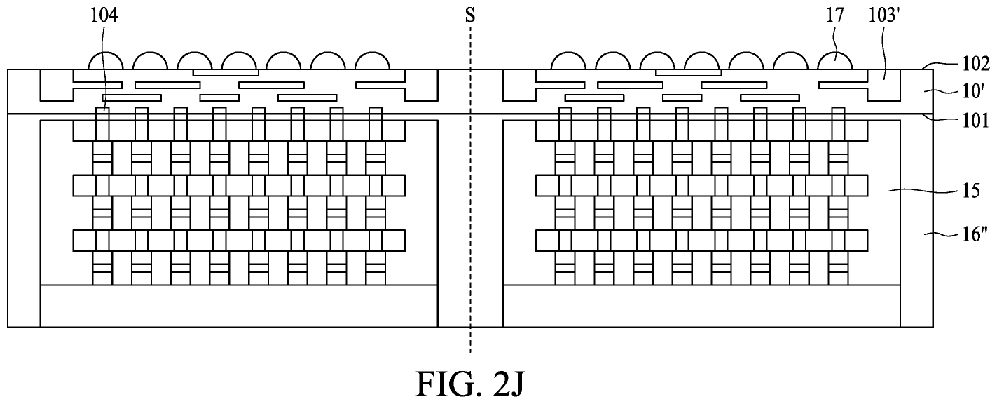

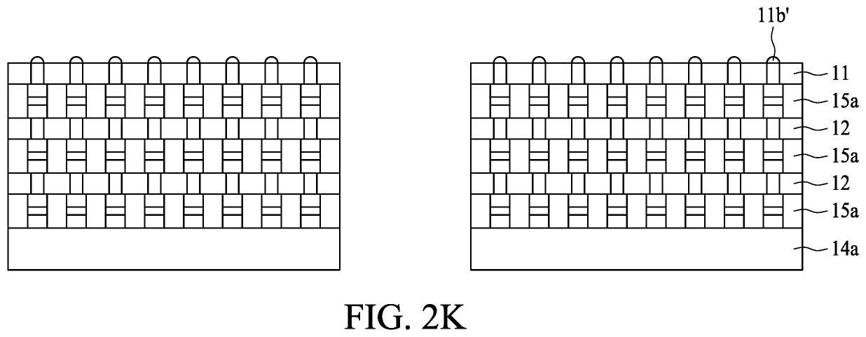

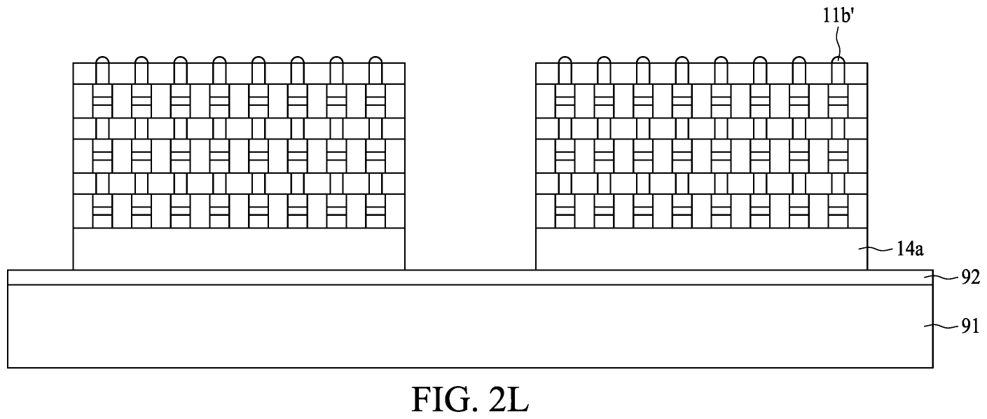

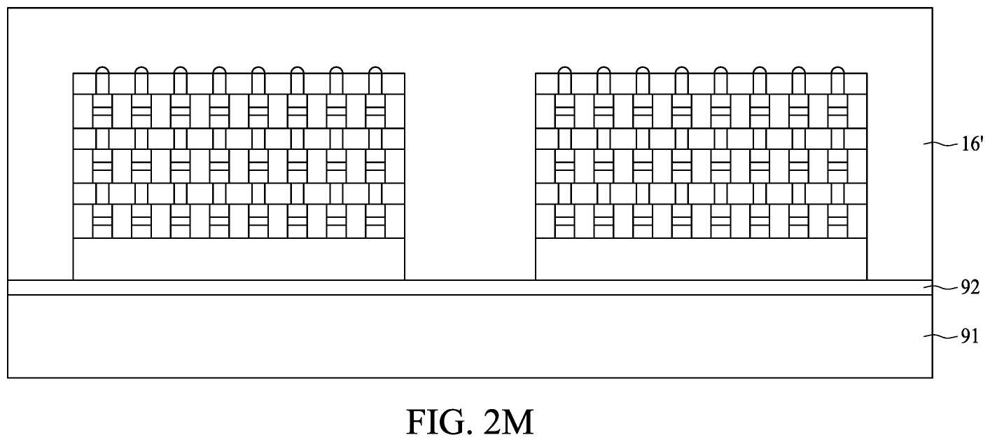

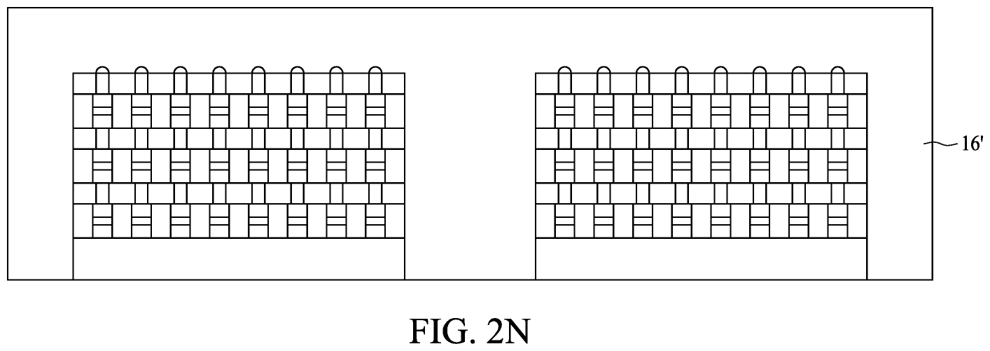

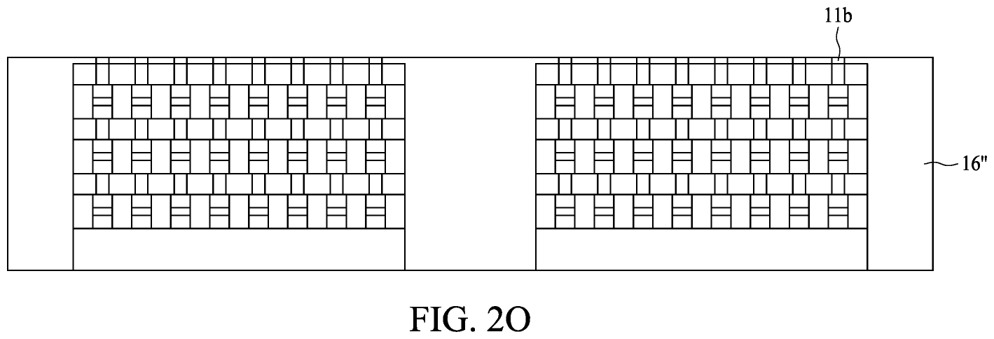

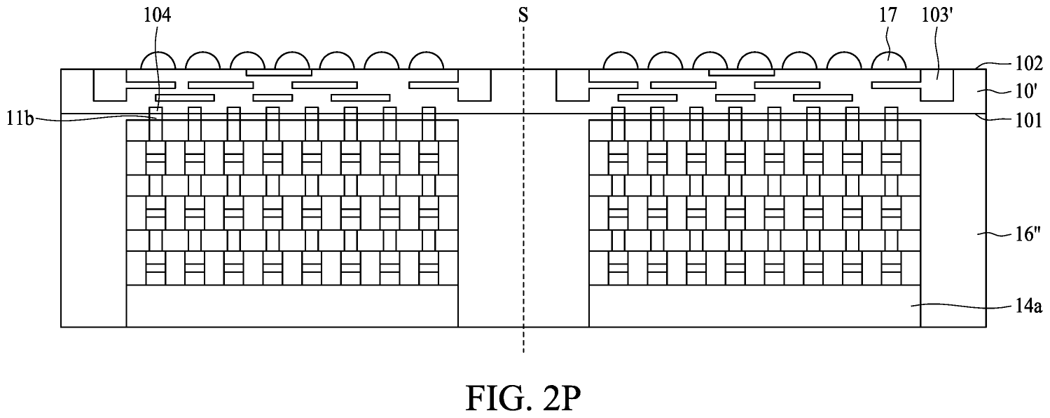

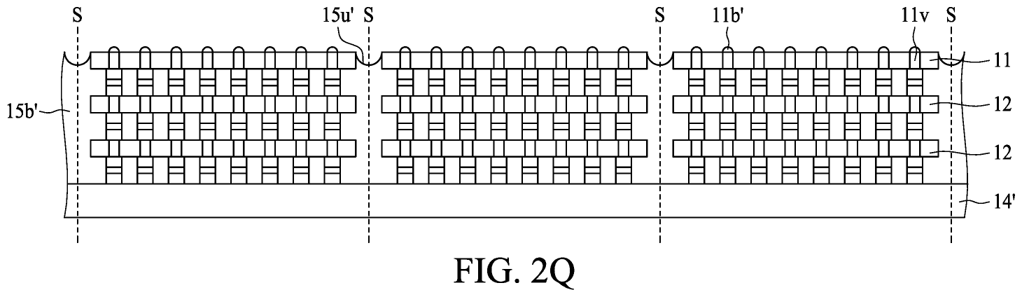

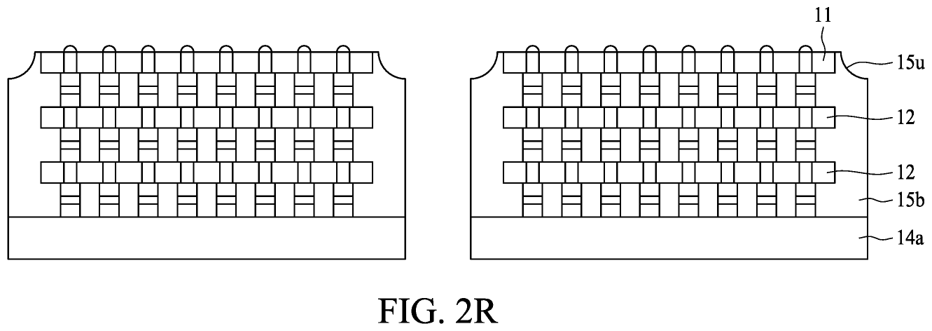

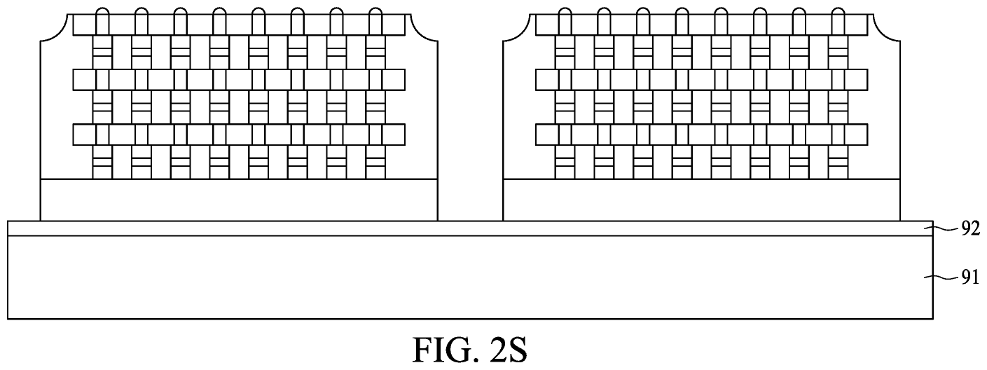

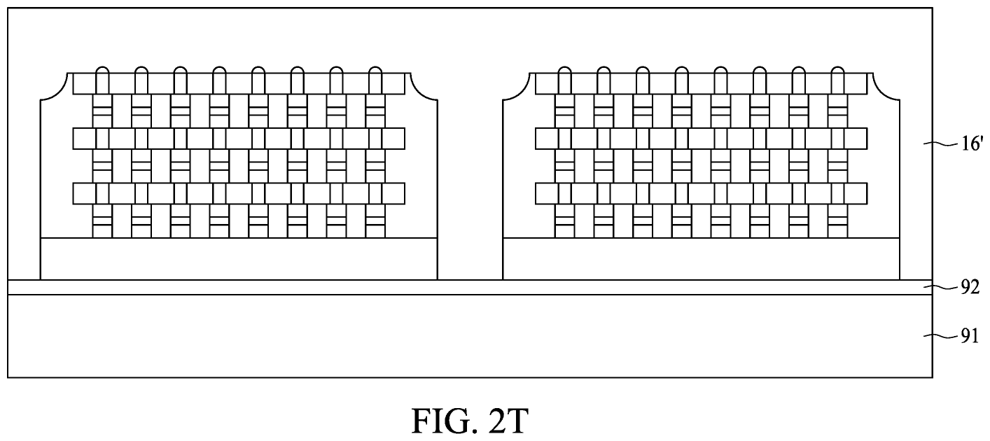

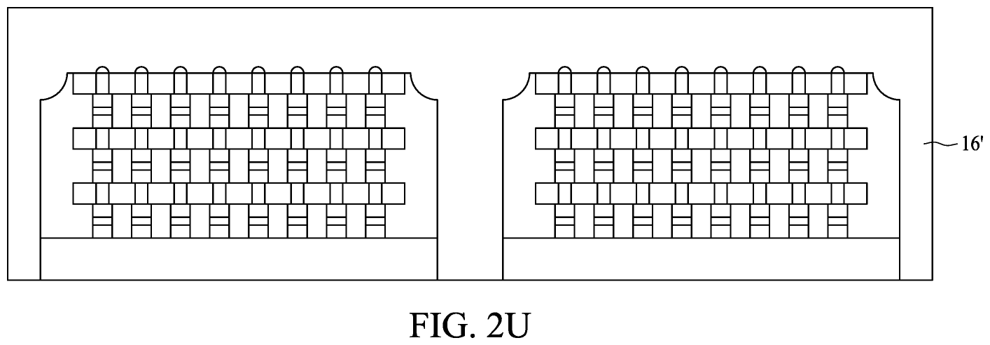

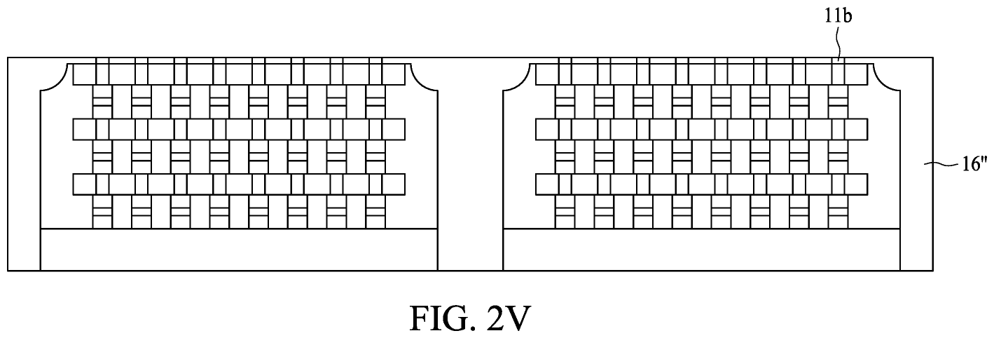

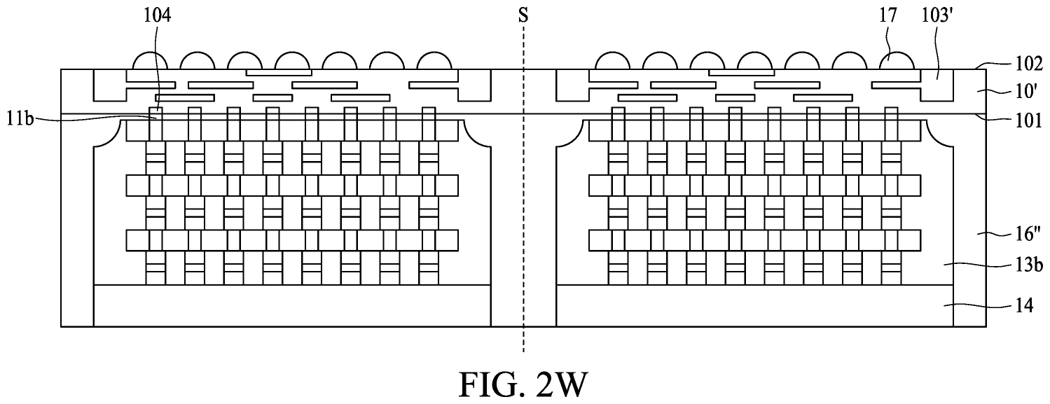

FIG. 2A, FIG. 2B, FIG. 2C, FIG. 4A, FIG. 4B, FIG. 4C, FIG. 4D and FIG. 4E illustrate various stages of another method for manufacturing a semiconductor device package accordance with some embodiments of the subject application.

FIG. 2A, FIG. 2B, FIG. 2C, FIG. 4F, FIG. 4G, FIG. 4H, FIG. 4I and FIG. 4J illustrate various stages of another method for manufacturing a semiconductor device package accordance with some embodiments of the subject application.

FIG. 2A, FIG. 2B, FIG. 2C, FIG. 4A, FIG. 4B, FIG. 4C, FIG. 4K and FIG. 4L illustrate various stages of another method for manufacturing a semiconductor device package accordance with some embodiments of the subject application.

FIG. 2A, FIG. 2B, FIG. 2C, FIG. 4F, FIG. 4G, FIG. 4H, FIG. 4M and FIG. 4N illustrate various stages of another method for manufacturing a semiconductor device package accordance with some embodiments of the subject application.

FIG. 2A, FIG. 2B, FIG. 4O, FIG. 4P, FIG. 4Q, FIG. 4R, FIG. 4S and FIG. 4T illustrate various stages of another method for manufacturing a semiconductor device package accordance with some embodiments of the subject application.

FIG. 2A, FIG. 2B, FIG. 4O, FIG. 4P, FIG. 4Q, FIG. 4R, FIG. 4U and FIG. 4V illustrate various stages of another method for manufacturing a semiconductor device package accordance with some embodiments of the subject application.

FIG. 5 is a cross-sectional view of another semiconductor device package in accordance with some embodiments of the present disclosure.

FIG. 5A is an enlarged view of structure in dotted circle K as shown in FIG. 5.

FIG. 5B is an enlarged view of structure in dotted box L as shown in FIG. 5.

FIG. 6A, FIG. 6B, FIG. 6C, FIG. 6D, FIG. 6E, FIG. 6F and FIG. 6G illustrate various stages of another method for manufacturing a semiconductor device package accordance with some embodiments of the subject application.

FIG. 7 is a cross-sectional view of another semiconductor device package in accordance with some embodiments of the present disclosure.

FIG. 7A is an enlarged view of structure in dotted box M as shown in FIG. 7.

FIG. 8A, FIG. 8B, FIG. 8C, FIG. 8D, FIG. 8E, FIG. 8F and FIG. 8G illustrate various stages of another method for manufacturing a semiconductor device package accordance with some embodiments of the subject application.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

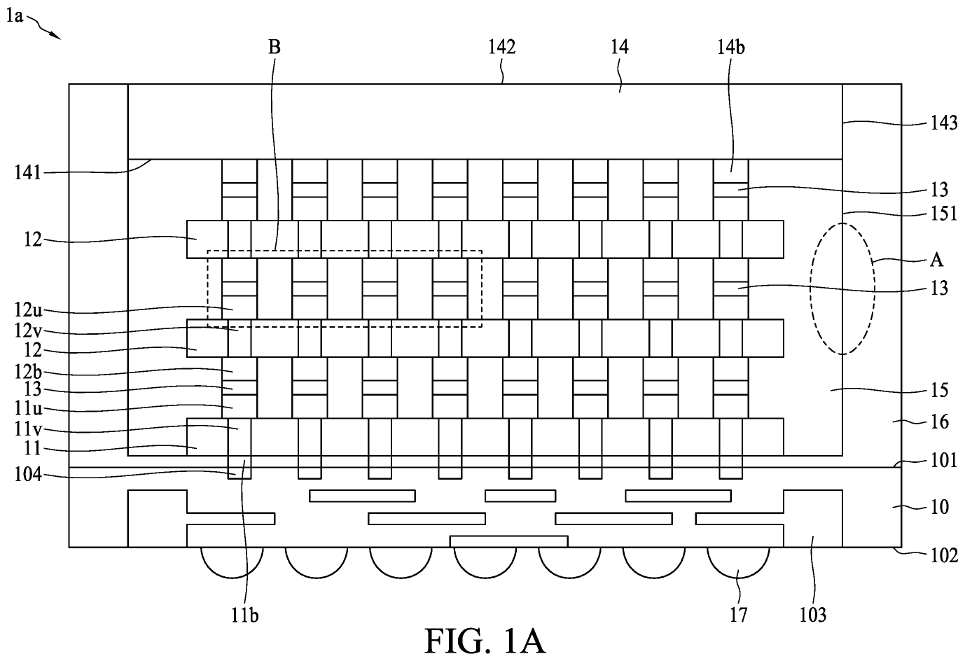

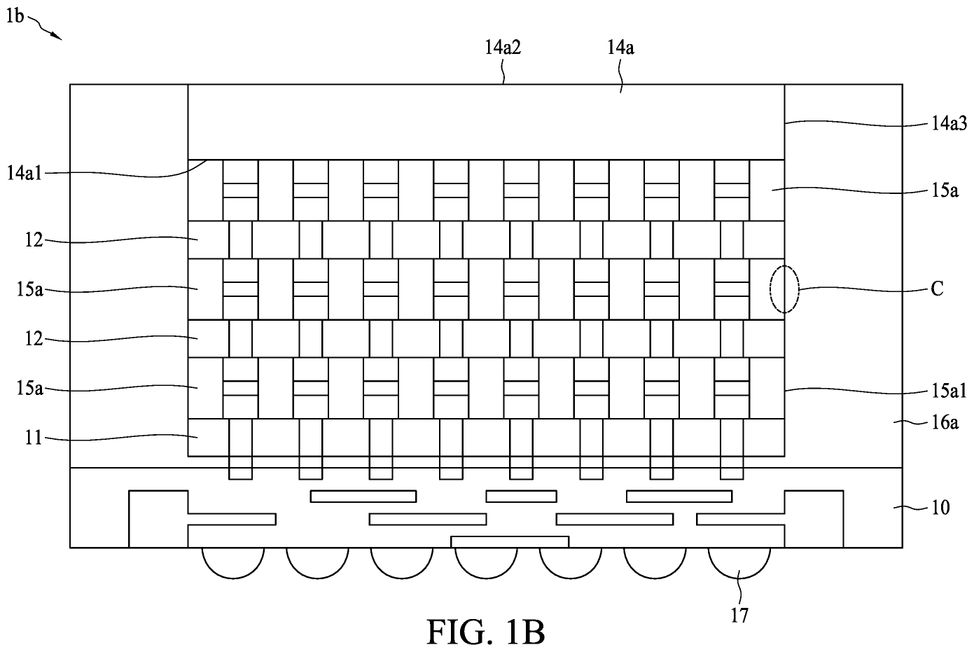

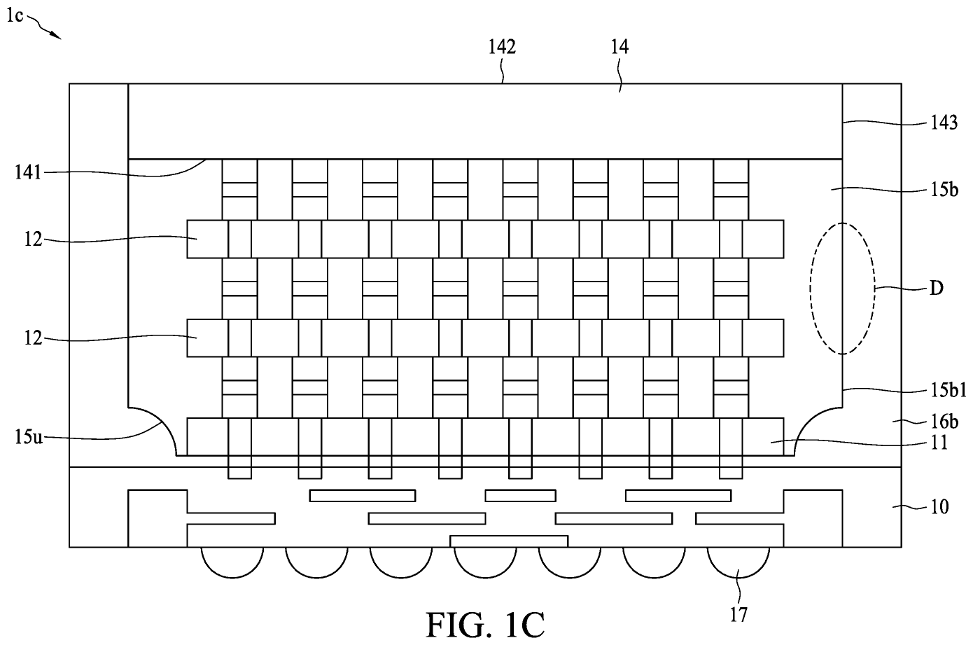

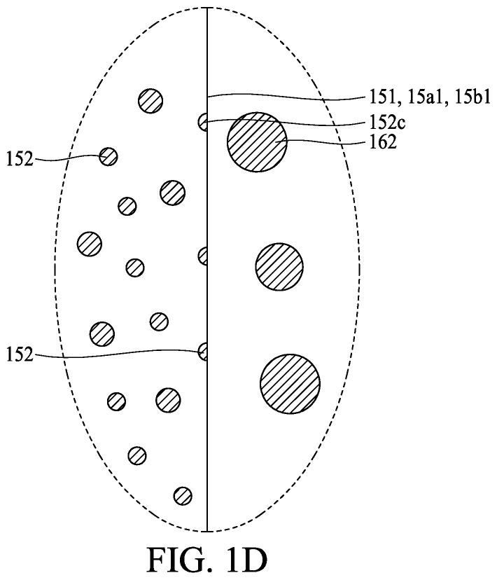

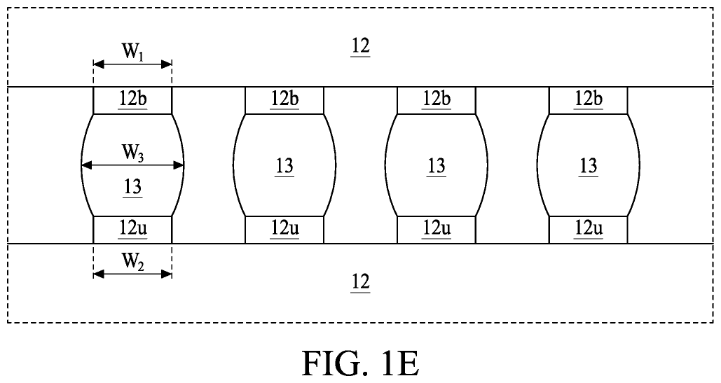

FIG. 1A is a cross-sectional view of a semiconductor device package in accordance with some embodiments of the present disclosure.

Referring to FIG. 1A, the semiconductor device package 1a may include a redistribution layer 10, semiconductor devices 11, 12 and 14, interconnections 13, an insulation body 15, another insulation body 16, and connection elements 17.

The redistribution layer 10 can include a redistribution structure 103 or circuitry 103. The redistribution layer 10 can include a single layer structure. The redistribution layer 10 can include a multi-layer structure. The redistribution layer 10 can include a substrate. The redistribution layer 10 can include a fan-out layer. The redistribution layer 10 may include insulation material(s) or dielectric material(s) (not denoted in FI. A). The redistribution layer 10 can include a core or relatively hard material. The redistribution layer 10 can include flexible or relatively soft material. The redistribution layer 10 may include a surface 101 and another surface 102 opposite the surface 101.

The redistribution structure 103 can include a some conductive elements, for example but is not limited to, conductive trace(s), pad(s), contact(s) (e.g. conductive contacts 104), via(s).

The redistribution structure 103 can have a pitch equal to or less than approximately 12 micrometer (μm). The redistribution structure 103 can have a line width/space equal to or less than approximately 12/12 μm. The redistribution structure 103 can have a pitch equal to or less than approximately 10 μm. The redistribution structure 103 can have a line width/space equal to or less than approximately 10/10 μm. The redistribution structure 103 can have a pitch equal to or less than approximately 8 μm. The redistribution structure 103 can have a line width/space equal to or less than approximately 8/8 μm. The redistribution structure 103 can have a pitch equal to or less than approximately 5 μm. The redistribution structure 103 can have a line width/space equal to or less than approximately 5/5 μm. The redistribution structure 103 can have a pitch equal to or less than approximately 2 μm. The redistribution structure 103 can have a line width/space equal to or less than approximately 2/2 μm.

The semiconductor device 11 can be disposed on the redistribution layer 10. The semiconductor device 11 may include, for example but is not limited to, a processor, a controller (e.g. a memory controller), a microcontroller (MCU), a memory die or other electronic component(s). The semiconductor device 11 can be electrically connected to the redistribution layer 10. The semiconductor device 11 can include interconnections 11b, conductive vias 11v and conductive contacts 11u.

The semiconductor device 11 can be bonded or attached to the redistribution layer 10 by the interconnections 11b. The semiconductor device 11 can be bonded or attached to the conductive contacts 104 of the redistribution layer 10 by the interconnections 11b. The interconnection 11b may include, for example but is not limited to, solder, adhesive (which may include conductive adhesive (e.g. resin mixed with conductive particles)), or other suitable bonding material(s).

The semiconductor device 12 can be disposed on the semiconductor device 11. The semiconductor device 12 may include, for example but is not limited to, a memory die or other electronic component(s). The semiconductor device 12 can be electrically connected to the semiconductor device 11. The semiconductor device 12 can include conductive contacts 12b, conductive vias 12v and conductive contacts 12u.

The semiconductor device 12 can be bonded or attached to the semiconductor device 11 by the interconnections 13. The conductive contacts 12b of the semiconductor device 12 can be bonded or attached to the conductive contacts 11u of the semiconductor device 11 by the interconnections 13. The interconnection 13 may include, for example but is not limited to, solder, adhesive (which may include conductive adhesive (e.g. resin mixed with conductive particles)), or other suitable bonding material(s).

Another semiconductor device 12 can be disposed on the semiconductor device 12. The semiconductor device 12 can be bonded or attached to another semiconductor device 12 by the interconnections 13. The conductive contacts 12b of the semiconductor device 12 can be bonded or attached to the conductive contacts 12u of another semiconductor device 12 by the interconnections 13.

The semiconductor device 14 can be disposed on the semiconductor device 12. The semiconductor device 14 may include, for example but is not limited to, a memory die or other electronic component(s). The semiconductor device 14 can be electrically connected to the semiconductor device 12. The semiconductor device 14 can include conductive contacts 14b.

The semiconductor device 14 can be bonded or attached to the semiconductor device 12 by the interconnections 13. The conductive contacts 14b of the semiconductor device 14 can be bonded or attached to the conductive contacts 12u of the semiconductor device 12 by the interconnections 13.

The semiconductor device 11 can be same or similar to the semiconductor device 12. The semiconductor device 11 can be different from the semiconductor device 12. The semiconductor device 11 can be same or similar to the semiconductor device 14. The semiconductor device 11 can be different from the semiconductor device 14. The semiconductor device 12 can be same or similar to the semiconductor device 14. The semiconductor device 12 can be different from the semiconductor device 14.

Although FIG. 1A illustrates a stack of four semiconductor devices 11, 12, and 14, however, it is contemplated that the stack as shown in FIG. 1A can include a more or less semiconductor devices.

The semiconductor device 14 can include a surface 141, another surface 142 opposite the surface 141, and a lateral surface 143 extended from the surface 141 to the surface 142. The semiconductor device 14 can have a width greater than the semiconductor device 11. The semiconductor device 14 can have a width greater than the semiconductor device 12.

The surface 142 can be exposed from the insulation body 16.

The insulation body 15 can encapsulate the semiconductor device 11. The insulation body 15 can encapsulate the semiconductor device 12. The insulation body 15 can encapsulate the semiconductor device 14. The insulation body 15 can encapsulate the conductive contact 14b. The insulation body 15 can encapsulate the interconnection 13. The insulation body 15 can encapsulate the conductive contact 12u. The insulation body 15 can encapsulate the conductive contact 12b. The insulation body 15 can encapsulate the conductive contact 11u.

The insulation body 15 can surround the semiconductor device 11. The insulation body 15 can surround the semiconductor device 12.

The insulation body 15 can include a lateral surface 151. The lateral surface 151 of the insulation body 15 can be substantially coplanar with the lateral surface 143 of the semiconductor device 14.

The insulation body 15 can include insulation or dielectric material. The insulation body 15 can include resin (e.g. bismaleimide triazine resin (BT). The insulation body 15 can include fillers or particles (e.g. SiO2 particles) (not shown in FIG. 1A). The insulation body 15 can include epoxy. The insulation body 15 can include underfill material. The insulation body 15 can include molding compound (e.g. epoxy molding compound (EMC)) or encapsulation material.

The insulation body 16 can encapsulate the semiconductor device 11. The insulation body 16 can encapsulate the insulation body 15. The insulation body 16 can encapsulate the semiconductor device 14. The insulation body 16 can encapsulate the interconnection 11b. The insulation body 16 can be disposed on the surface 101 of the redistribution layer 10. The insulation body 16 can be disposed between the surface 101 of the redistribution layer 10 and the semiconductor device 11. A portion of the insulation 16 can extend between the surface 101 of the redistribution layer 10 and the semiconductor device 11 and function as a mold lock.

The insulation body 16 can surround the semiconductor device 11. The insulation body 16 can surround the semiconductor device 12. The insulation body 16 can surround the semiconductor device 14. The insulation body 16 can surround the insulation body 15. The insulation body 16 can be in direct contact with the insulation body 15.

The insulation body 16 can include insulation or dielectric material. The insulation body 16 can include fillers or particles (e.g. SiO2 particles) (not shown in FIG. 1A). The insulation body 16 can include epoxy. The insulation body 16 can include molding compound (e.g. epoxy molding compound (EMC)) or encapsulation material. The insulation body 16 can include material same or similar to the insulation body 15. The insulation body 16 can include material different from the insulation body 15.

The connection elements 17 can be disposed on the surface 102 of the redistribution layer 10. The connection elements 17 can include solder or other suitable bonding material(s).

FIG. 1B is a cross-sectional view of another semiconductor device package in accordance with some embodiments of the present disclosure.

Referring to FIG. 1B, the semiconductor device package 1b can be similar to the semiconductor device package 1a as described and illustrated with reference to FIG. 1A, except that the semiconductor device 14 is replaced by a semiconductor device 14a, the insulation body 15 is replaced by an insulation body 15a, and the insulation body 16 is replaced by an insulation body 16a.

The semiconductor device 14a can be similar to the semiconductor device 14 as described and illustrated with reference to FIG. 1A, except that the semiconductor device 14a may have a relatively less width than semiconductor device 14. A width of the semiconductor device 14a can be substantially same to the semiconductor device 11. A width of the semiconductor device 14a can be substantially same to the semiconductor device 12.

The semiconductor device 14a can include a surface 14a1, another surface 14a2 opposite the surface 14a1, and a lateral surface 14a3 extended from the surface 14a1 to the surface 14a2.

The surface 14a2 can be exposed from the insulation body 16a.

The insulation body 15a can be similar to the insulation body 15 as described and illustrated with reference to FIG. 1A, except that the insulation body 15a may have a relatively less width than insulation body 15.

The insulation body 15a can encapsulate the semiconductor device 11. The insulation body 15a can encapsulate the semiconductor device 12. The insulation body 15a can encapsulate the semiconductor device 14a. The insulation body 15a can encapsulate the conductive contact 14b. The insulation body 15a can encapsulate the interconnection 13. The insulation body 15a can encapsulate the conductive contact 12u. The insulation body 15a can encapsulate the conductive contact 12b. The insulation body 15a can encapsulate the conductive contact 11u.

The insulation body 15a can include a lateral surface 15a1. The lateral surface 15a1 of the insulation body 15a can be substantially coplanar with the lateral surface 14a3 of the semiconductor device 14a. The lateral surface 15a1 of the insulation body 15a can be substantially coplanar with a lateral surface of the semiconductor device 12 (not denoted in FIG. 1). The lateral surface 15a1 of the insulation body 15a can be substantially coplanar with a lateral surface of the semiconductor device 11 (not denoted in FIG. 1).

The insulation body 15a can include insulation or dielectric material. The insulation body 15a can include resin (e.g. bismaleimide triazine resin (BT). The insulation body 15a can include fillers or particles (e.g. SiO2 particles) (not shown in FIG. 1). The insulation body 15a can include epoxy. The insulation body 15a can include underfill material. The insulation body 15a can include molding compound (e.g. epoxy molding compound (EMC)) or encapsulation material.

The insulation body 16a can be similar to the insulation body 16 as described and illustrated with reference to FIG. 1A, except that the insulation body 16a may have a relatively great volume in or around the periphery (e.g. a zone from the lateral surface 14a3 of the semiconductor device 14a to an edge of the insulation body 16a).

The insulation body 16a can encapsulate the semiconductor device 11. The insulation body 16a can encapsulate the insulation body 15a. The insulation body 16a can encapsulate the semiconductor device 14a. The insulation body 16a can encapsulate the interconnection 11b. The insulation body 16a can be disposed on the surface 101 of the redistribution layer 10. The insulation body 16a can be disposed between the surface 101 of the redistribution layer 10 and the semiconductor device 11.

The insulation body 16a can surround the semiconductor device 11. The insulation body 16a can surround the semiconductor device 12. The insulation body 16a can surround the semiconductor device 14a. The insulation body 16a can surround the insulation body 15a. The insulation body 16a can be in direct contact with the insulation body 15a.

The insulation body 16a can include insulation or dielectric material. The insulation body 16a can include fillers or particles (e.g. SiO2 particles) (not shown in FIG. 1). The insulation body 16a can include epoxy. The insulation body 16a can include molding compound (e.g. epoxy molding compound (EMC)) or encapsulation material. The insulation body 16a can include material same or similar to the insulation body 15a. The insulation body 16a can include material different from the insulation body 15a.

The structure in the dotted circle C can be similar to the structure in the dotted circle A as shown in FIG. 1A.

FIG. 1C is a cross-sectional view of another semiconductor device package in accordance with some embodiments of the present disclosure.

Referring to FIG. 1C, the semiconductor device package 1c can be similar to the semiconductor device package 1a as described and illustrated with reference to FIG. 1A, except that the insulation body 15 is replaced by an insulation body 15b, and the insulation body 16 is replaced by an insulation body 16b.

The insulation body 15b can be similar to the insulation body 15 as described and illustrated with reference to FIG. 1A, except that the insulation body 15b may have an indentation 15u.

The insulation body 15b can include a cut 15u. The insulation body 15b can include a concave cut 15u. The insulation body 15b can include a concave surface 15u. The insulation body 15b can include a curve surface 15u.

The concave surface 15u can surround the semiconductor device 11. The concave surface 15u can be adjacent to the semiconductor device 11. The concave surface 15u can include a rectangular shape. The concave surface 15u can include a rectangular-like shape. The concave surface 15u can extend from the semiconductor device 11 to an elevation lower than the semiconductor device 12.

The insulation body 15b can encapsulate the semiconductor device 11. The insulation body 15b can encapsulate the semiconductor device 12. The insulation body 15b can encapsulate the semiconductor device 14. The insulation body 15b can encapsulate the conductive contact 14b. The insulation body 15b can encapsulate the interconnection 13. The insulation body 15b can encapsulate the conductive contact 12u. The insulation body 15b can encapsulate the conductive contact 12b. The insulation body 15b can encapsulate the conductive contact 11u.

The insulation body 15b can include a lateral surface 15b1. The lateral surface 15b1 of the insulation body 15b can be substantially coplanar with the lateral surface 143 of the semiconductor device 14.

The insulation body 15b can include insulation or dielectric material. The insulation body 15b can include resin (e.g. bismaleimide triazine resin (BT). The insulation body 15b can include fillers or particles (e.g. SiO2 particles) (not shown in FIG. 1C). The insulation body 15b can include epoxy. The insulation body 15b can include underfill material. The insulation body 15b can include molding compound (e.g. epoxy molding compound (EMC)) or encapsulation material.

The insulation body 16b can be similar to the insulation body 16 as described and illustrated with reference to FIG. 1A, except that the insulation body 16b may further include a convex portion or a convex surface (not denoted in FIG. 1C).

The convex portion of the insulation body 16b can engage with the indentation 15u of the insulation body 15b. The convex surface of the insulation body 16b can engage with the concave surface 15u of the insulation body 15b.

The insulation body 16b can encapsulate the semiconductor device 11. The insulation body 16b can encapsulate the insulation body 15b. The insulation body 16b can encapsulate the semiconductor device 14. The insulation body 16b can encapsulate the interconnection 11b. The insulation body 16b can be disposed on the surface 101 of the redistribution layer 10. The insulation body 16b can be disposed between the surface 101 of the redistribution layer 10 and the semiconductor device 11.

The insulation body 16b can surround the semiconductor device 11. The insulation body 16b can surround the semiconductor device 12. The insulation body 16b can surround the semiconductor device 14. The insulation body 16b can surround the insulation body 15b. The insulation body 16b can be in direct contact with the insulation body 15b.

The insulation body 16b can include insulation or dielectric material. The insulation body 16b can include fillers or particles (e.g. SiO2 particles) (not shown in FIG. 1C). The insulation body 16b can include epoxy. The insulation body 16b can include molding compound (e.g. epoxy molding compound (EMC)) or encapsulation material. The insulation body 16b can include material same or similar to the insulation body 15b. The insulation body 16b can include material different from the insulation body 15b.

The structure in the dotted circle D can be similar to the structure in the dotted circle A as shown in FIG. 1A.

FIG. 1D is an enlarged view of structure in dotted circle A as shown in FIG. 1A.

Referring to FIG. 1D, the insulation body 15 may have some fillers or particles 152. The insulation body 16 may have some fillers or particles 162. Some of the particles 152 can have a flat surface 152c.

The flat surface 152c can be substantially coplanar with the lateral surface 151 of the insulation body 15 (or the lateral surface 15a1 of the insulation body 15a as shown in FIG. 1B, or the lateral surface 15b1 of the insulation body 15b as shown in FIG. 1C).

The flat surface 152c can be substantially aligned with the lateral surface 151 of the insulation body 15 (or the lateral surface 15a1 of the insulation body 15a as shown in FIG. 1B, or the lateral surface 15b1 of the insulation body 15b as shown in FIG. 1C).

The flat surface 152c can be observed on the edge 151 or boundary 151 of the insulation body 15 (or the boundary 15a1 of the insulation body 15a as shown in FIG. 1B, or the boundary 15b1 of the insulation body 15b as shown in FIG. 1C). The flat surface 152c can be observed on the interface 151 between the insulation body 15 and the insulation body 16 (or the interface 15a1 between the insulation body 15a and the insulation body 16a as shown in FIG. 1B, or the interface 15b1 between the insulation body 15b and the insulation body 16b as shown in FIG. 1C).

The flat surface 152c can be in direct contact with the insulation body 16.

An average size of particles 152 can be substantially less than an average size of particles 162. The particles 152 can have an average size or dimension ranged from approximately 0.8 μm to approximately 1.0 μm. The particles 162 can have an average size or dimension ranged from approximately 10.0 μm to approximately 50.0 μm. The particles 162 can have an average size substantially greater than 50.0 μm.

A ratio of a maxima size to a minimum size with respect to the particles 152 can be substantially less than a ratio of a maxima size to a minimum size with respect to the particles 162. A ratio of a maxima particle 152 to a minimum particle 152 in size can be substantially equal to 3. A ratio of a maxima particle 152 to a minimum particle 152 in size can be substantially less than 3. A ratio of a maxima particle 162 to a minimum particle 162 in size can be substantially equal to 5. A ratio of a maxima particle 162 to a minimum particle 162 in size can be substantially greater than 5. The insulation body 15 can have relatively better particle uniformity than the insulation body 16.

An average content of the particles 152 in the insulation body 15 can be substantially greater than an average content of the particles 162 in the insulation body 16. The insulation body 15 can have an average filler content substantially equal to or greater than 80%. The insulation body 16 can have an average filler content substantially equal to or less than 70%.

FIG. 1E is an enlarged view of structure in dotted box B as shown in FIG. 1A.

Referring to FIG. 1E, the conductive contact 12b of the semiconductor device 12 may have a width W₁, the conductive contact 12u of the semiconductor device 12 may have a width W₂, and the interconnection 13 can have a maximum width W₃.

The width W₃ can be substantially same to the width W₁. The width W₃ can be substantially same to the width W₂. The width W₃ can be substantially greater than the width W₁. The width W₃ can be substantially greater than the width W₂. The width W₃ can be substantially equal to 1.2 times the width W₁. The width W₃ can be substantially less than 1.2 times the width W₁. The width W₃ can be substantially equal to 1.2 times the width W₂. The width W₃ can be substantially less than 1.2 times the width W₂.

The interconnection 13 can be formed by laser assisted bonding (LAB) technique.

FIG. 2A, FIG. 2B, FIG. 2C, FIG. 2D, FIG. 2E, FIG. 2F, FIG. 2G, FIG. 2H, FIG. 2I and FIG. 2J illustrate various stages of a method for manufacturing a semiconductor device package accordance with some embodiments of the subject application.

Referring to FIG. 2A, a wafer 14′ can be provided. The wafer 14′ can include some semiconductor devices 14 or 14a. The wafer 14′ can include some conductive contacts 14b.

Referring to FIG. 2B, some semiconductor devices 12 can be attached or bonded to the wafer 14′ by flip-chip bond technique, LAB technique or other suitable technique(s). The semiconductor devices 12 can be attached or bonded to the wafer 14′ by interconnections 13.

Referring to FIG. 2C, some other semiconductor devices 12 can be attached, bonded or stacked to the semiconductor devices 12 as shown in FIG. 2B, by LAB technique or other suitable technique(s). Some semiconductor devices 11 can be attached, bonded or stacked to the semiconductor devices 12 by LAB technique or other suitable technique(s). An insulation material 15′ may be formed to encapsulate the stacked structures. The insulation material 15′ can be formed by potting technique, dispensing technique, molding technique or other suitable technique(s).

Referring to FIG. 2D, some conductive elements 11b′ can be formed on the conductive vias 11v of the semiconductor device 11 as shown in FIG. 2C.

Referring to FIG. 2E, a cutting operation or a singulation operation may be performed along the scribe lines S as shown in FIG. 2D to form some stacked structures as shown in FIG. 2E. The cutting operation or singulation operation can be performed by a tool or knife of a relatively less width.

Referring to FIG. 2F, the stacked structures as shown in FIG. 2E can be disposed on a carrier 91. The stacked structures as shown in FIG. 2E can be disposed on a release layer 92 provided on the carrier 91.

Referring to FIG. 2G, insulation material 16′ can be formed on the release layer 92 to encapsulate the stacked structures as shown in FIG. 2F.

Referring to FIG. 2H, the release layer 91 and the carrier 92 can be removed.

Referring to FIG. 2I, a portion of the insulation material 16′ and the conductive elements 11b′ can be removed to expose the interconnections 11b. The portion of the insulation material 16′ can be removed to form insulation material 16″.

Referring to FIG. 2J, an redistribution layer 10′ can be formed on the structure as shown in FIG. 2I. The redistribution layer 10′ can be electrically connected to the interconnections 11b. Some connection elements 17 may be formed on the redistribution layer 10′. The connection elements 17 can be electrically connected to redistribution layer 10′. A cutting operation or a singulation operation may be performed along the scribe lines S as shown in FIG. 2J to form some semiconductor device packages 1a described and illustrated with reference to FIG. 1A.

FIG. 2A, FIG. 2B, FIG. 2C, FIG. 2D, FIG. 2K, FIG. 2L, FIG. 2M, FIG. 2N, FIG. 2O and FIG. 2P illustrate various stages of another method for manufacturing a semiconductor device package accordance with some embodiments of the subject application.

Referring to FIG. 2K, a cutting operation or a singulation operation may be performed along the scribe lines S as shown in FIG. 2D to form some stacked structures as shown in FIG. 2K. The cutting operation or singulation operation can be performed by a tool or knife of a relatively great width.

Referring to FIG. 2L, the stacked structures as shown in FIG. 2K can be disposed on a carrier 91. The stacked structures as shown in FIG. 2K can be disposed on a release layer 92 provided on the carrier 91.

Referring to FIG. 2M, insulation material 16′ can be formed on the release layer 92 to encapsulate the stacked structures on the release layer 92 as shown in FIG. 2L.

Referring to FIG. 2N, the release layer 91 and the carrier 92 can be removed.

Referring to FIG. 2O, a portion of the insulation material 16′ and the conductive elements 11b′ can be removed to expose the interconnections 11b. The portion of the insulation material 16′ can be removed to form insulation material 16″.

Referring to FIG. 2P, an redistribution layer 10′ can be formed on the structure as shown in FIG. 2O. The redistribution layer 10′ can be electrically connected to the interconnections 11b. Some connection elements 17 may be formed on the redistribution layer 10′. The connection elements 17 can be electrically connected to redistribution layer 10′. A cutting operation or a singulation operation may be performed along the scribe lines S as shown in FIG. 2P to form some semiconductor device packages 1b described and illustrated with reference to FIG. 1B.

FIG. 2A, FIG. 2B, FIG. 2Q, FIG. 2R, FIG. 2S, FIG. 2T, FIG. 2U, FIG. 2V, and FIG. 2W illustrate various stages of another method for manufacturing a semiconductor device package accordance with some embodiments of the subject application.

Referring to FIG. 2Q, some other semiconductor devices 12 can be attached, bonded or stacked to the semiconductor devices 12 as shown in FIG. 2B, by LAB technique or other suitable technique(s). Some semiconductor devices 11 can be attached, bonded or stacked to the semiconductor devices 12 by LAB technique or other suitable technique(s).

Some conductive elements 11b′ can be formed on the conductive vias 11v of the semiconductor device 11 as shown in FIG. 2Q. An insulation material 15b′ may be formed to encapsulate the stacked structures. The insulation material 15b′ can be formed by dispensing technique or other suitable technique(s). A concave surface 15u′ can be formed in the operation as shown in FIG. 2Q.

Referring to FIG. 2R, a cutting operation or a singulation operation may be performed along the scribe lines S as shown in FIG. 2Q to form some stacked structures as shown in FIG. 2R.

Referring to FIG. 2S, the stacked structures as shown in FIG. 2R can be disposed on a carrier 91. The stacked structures as shown in FIG. 2R can be disposed on a release layer 92 provided on the carrier 91.

Referring to FIG. 2T, insulation material 16′ can be formed on the release layer 92 to encapsulate the stacked structures as shown in FIG. 2S.

Referring to FIG. 2U, the release layer 91 and the carrier 92 can be removed.

Referring to FIG. 2V, a portion of the insulation material 16′ and the conductive elements 11b′ can be removed to expose the interconnections 11b. The portion of the insulation material 16′ can be removed to form insulation material 16″.

Referring to FIG. 2W, an redistribution layer 10′ can be formed on the structure as shown in FIG. 2V. The redistribution layer 10′ can be electrically connected to the interconnections 11b. Some connection elements 17 may be formed on the redistribution layer 10′. The connection elements 17 can be electrically connected to redistribution layer 10′. A cutting operation or a singulation operation may be performed along the scribe lines S as shown in FIG. 2W to form some semiconductor device packages 1c described and illustrated with reference to FIG. 1C.

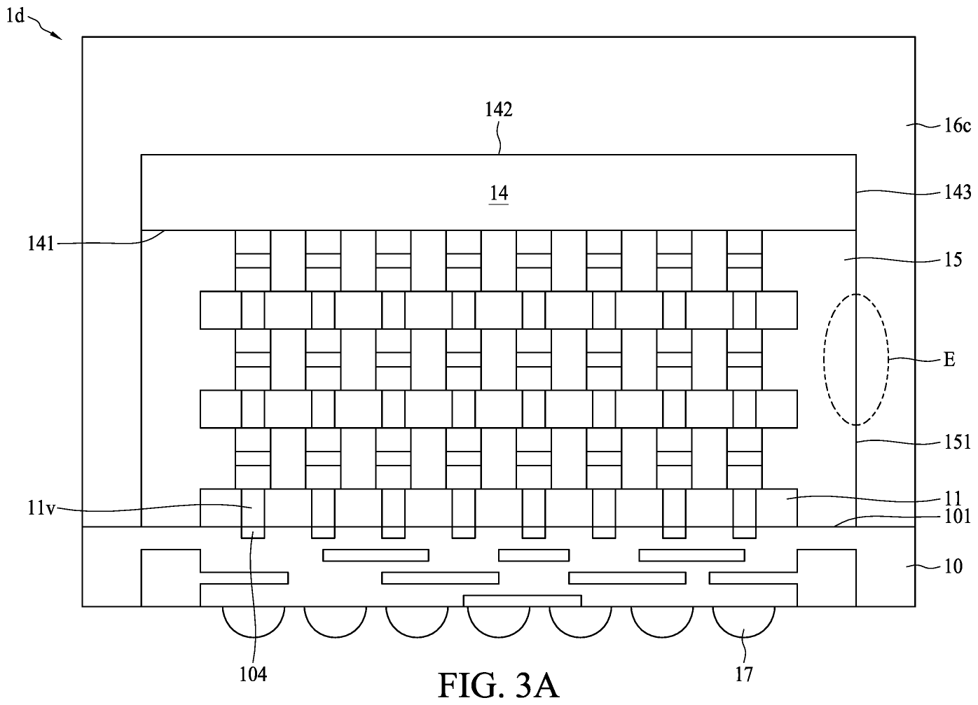

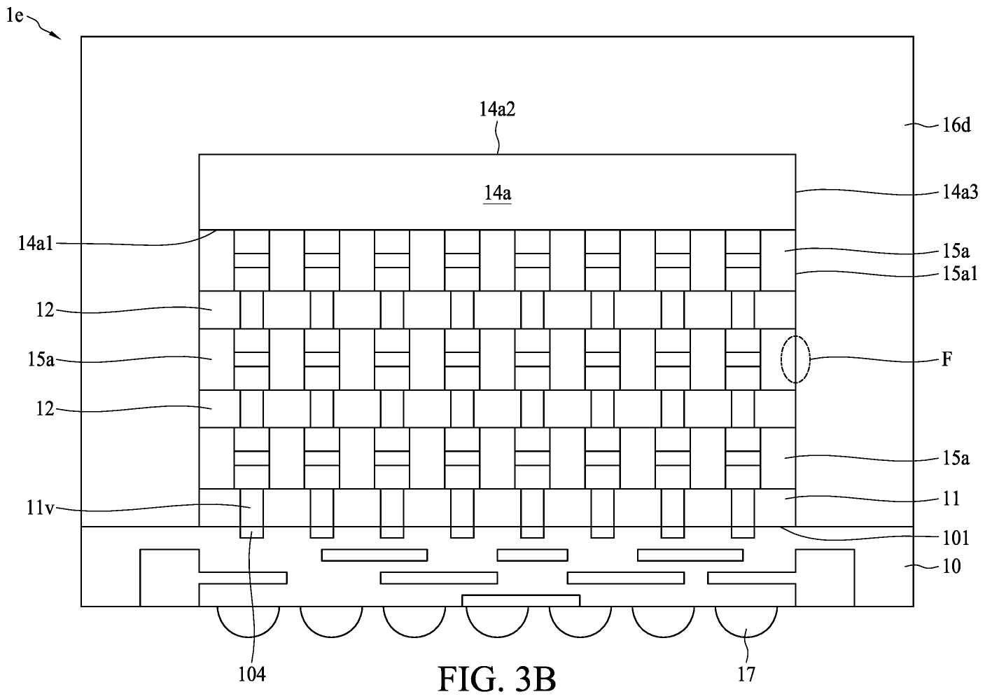

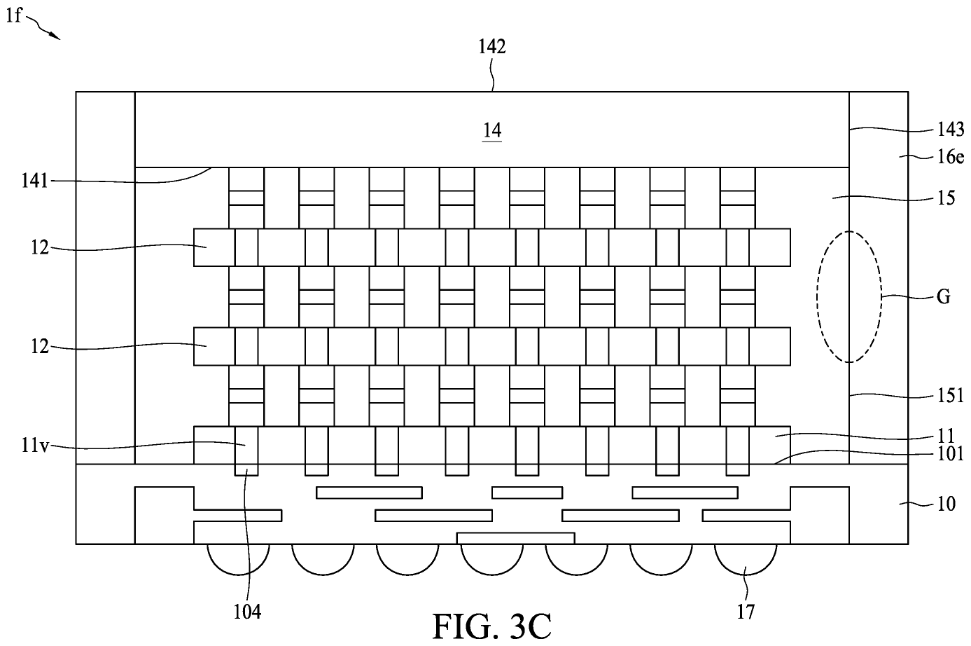

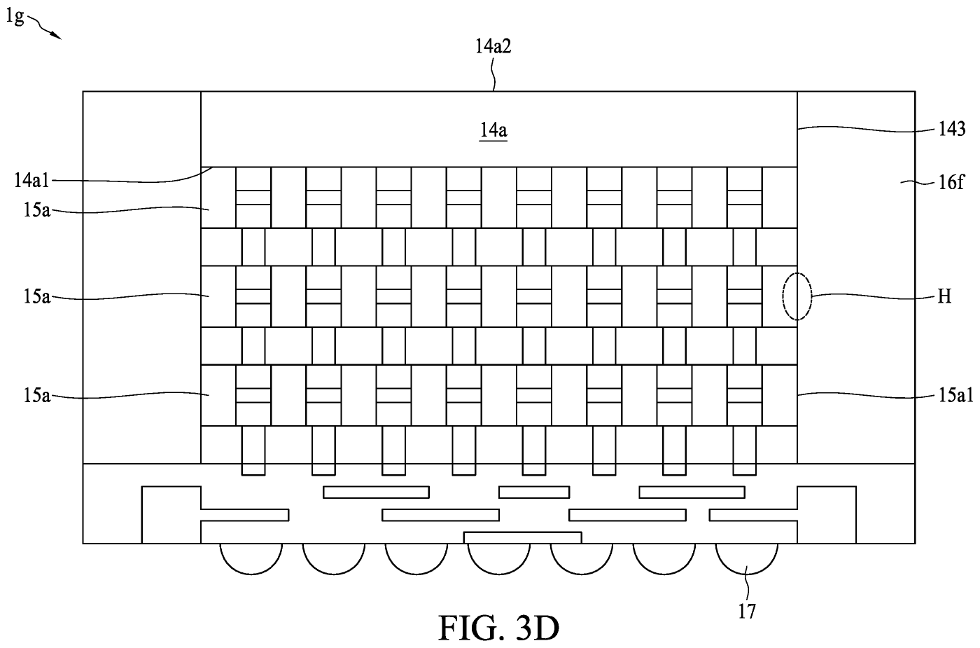

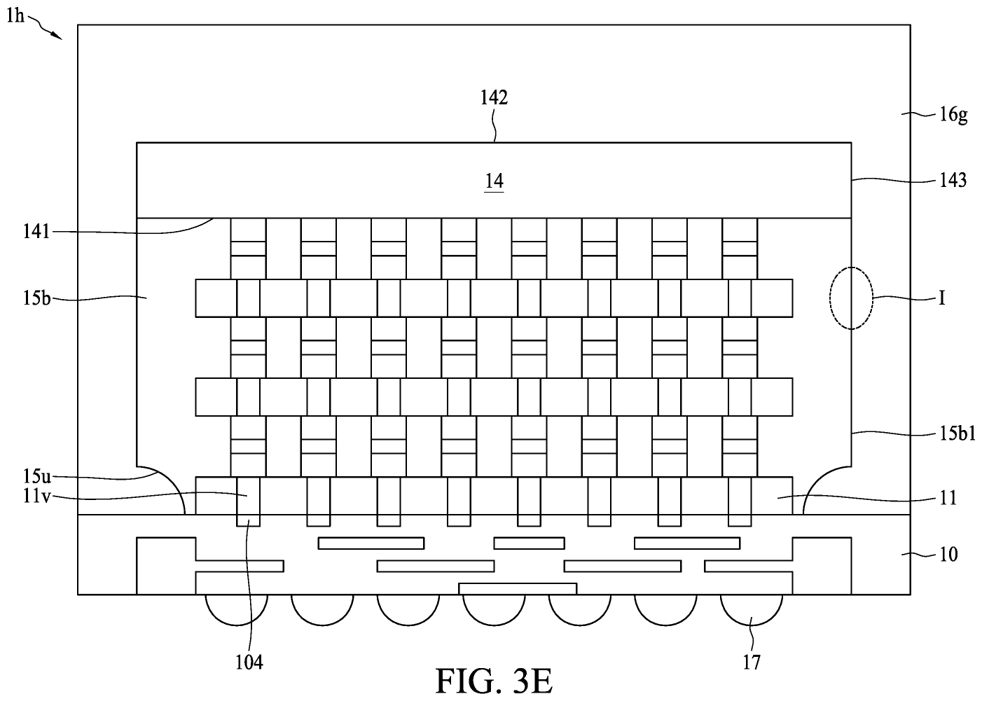

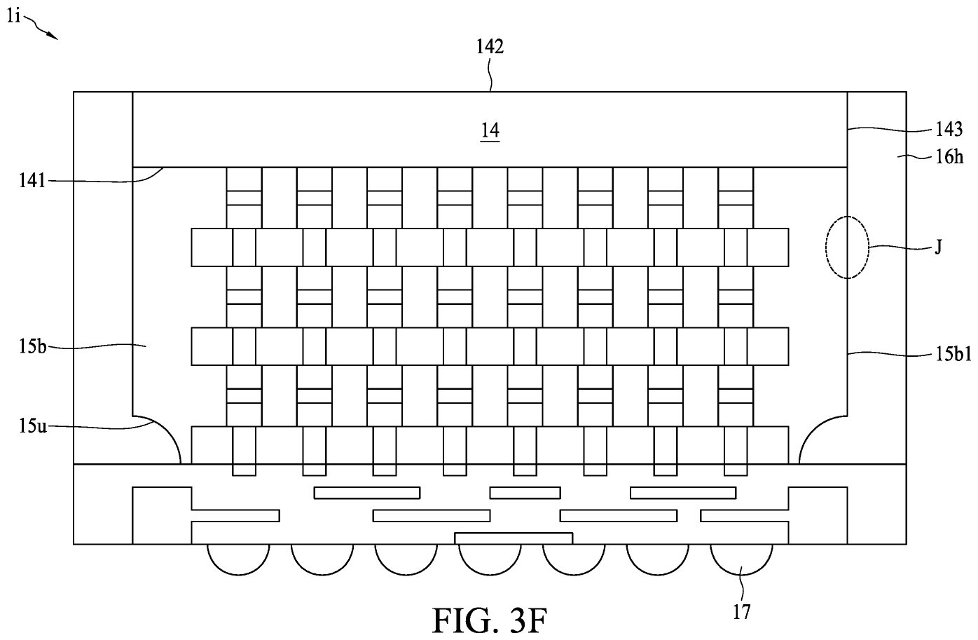

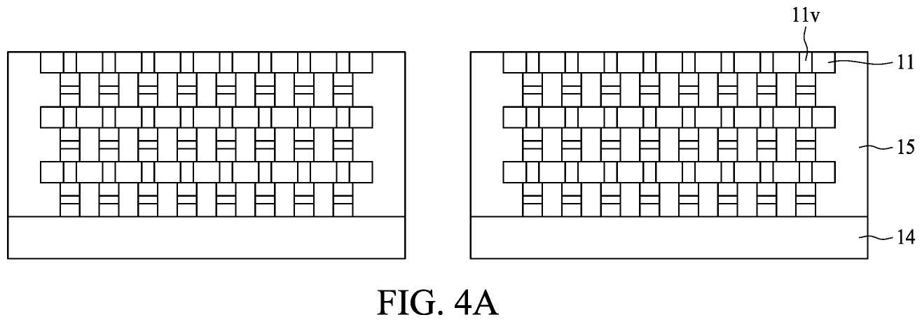

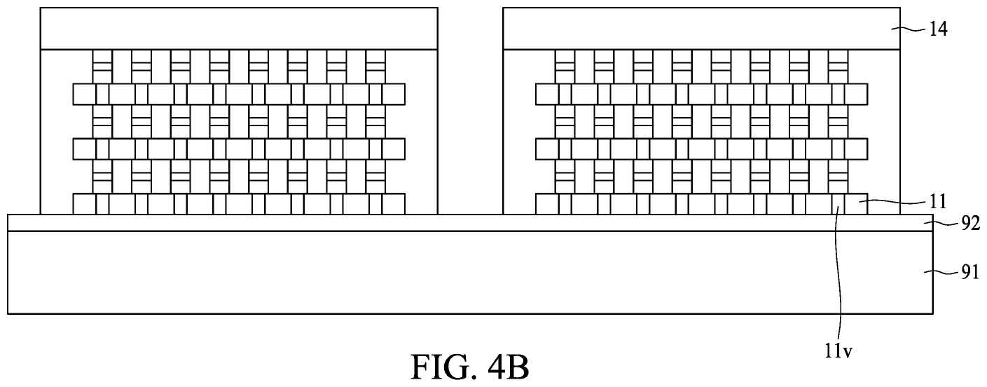

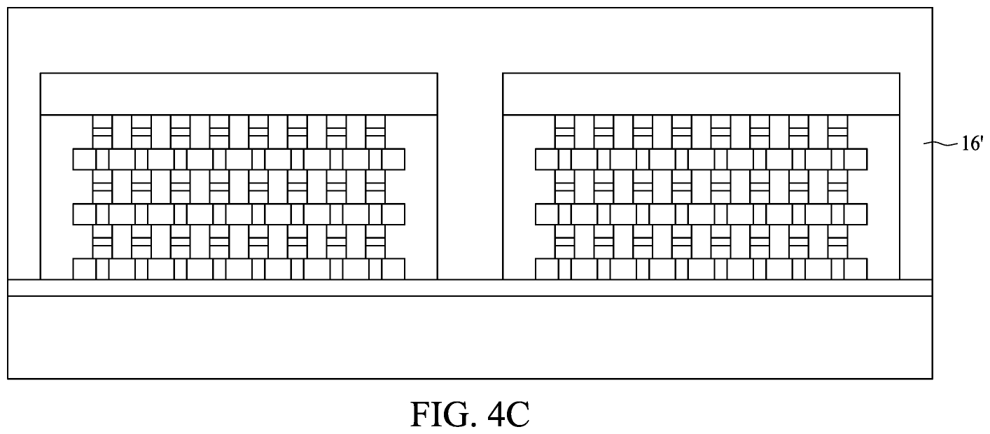

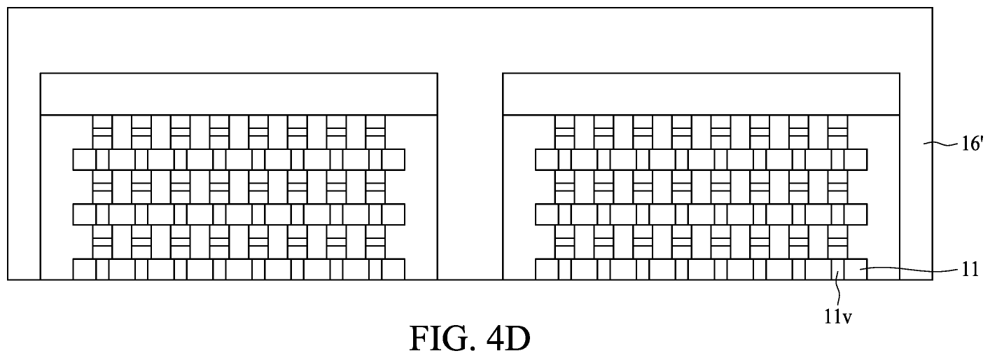

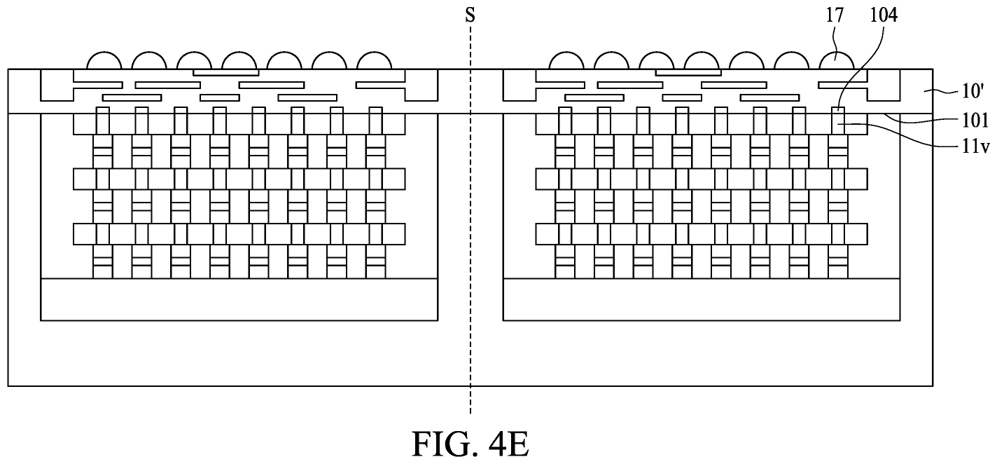

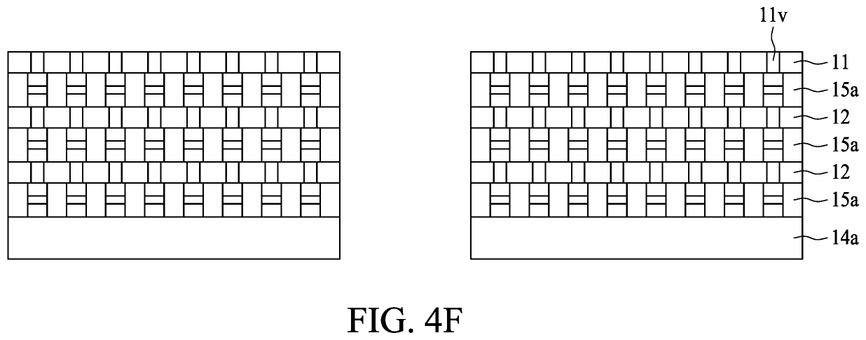

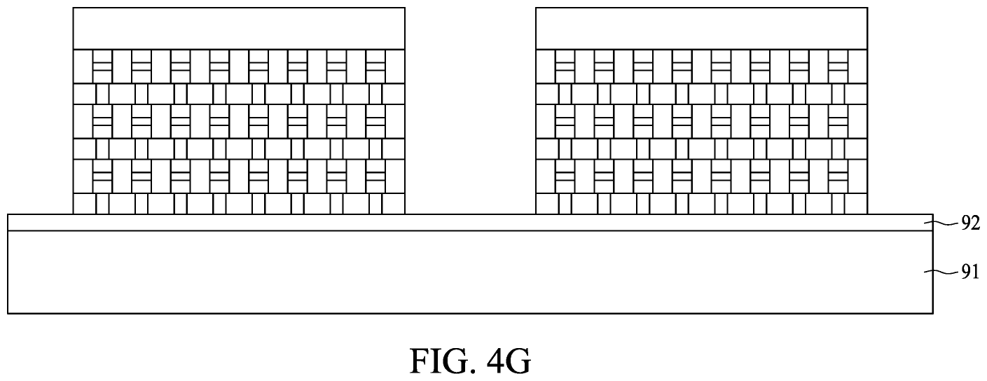

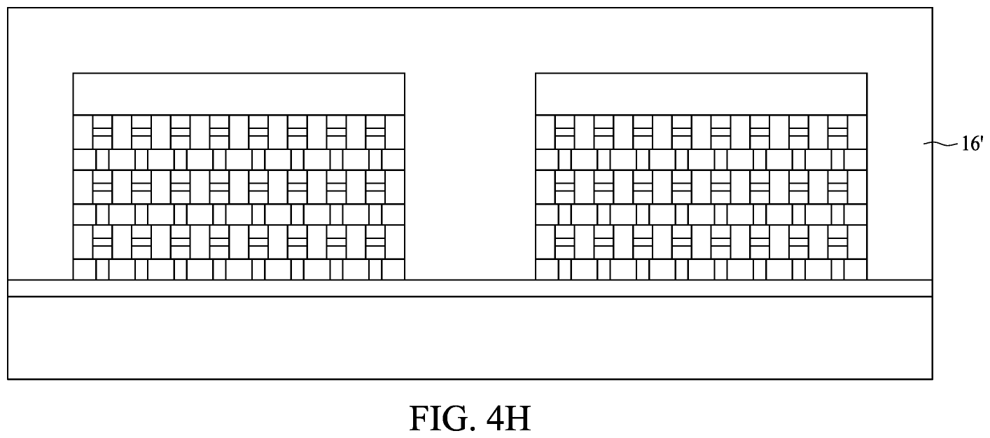

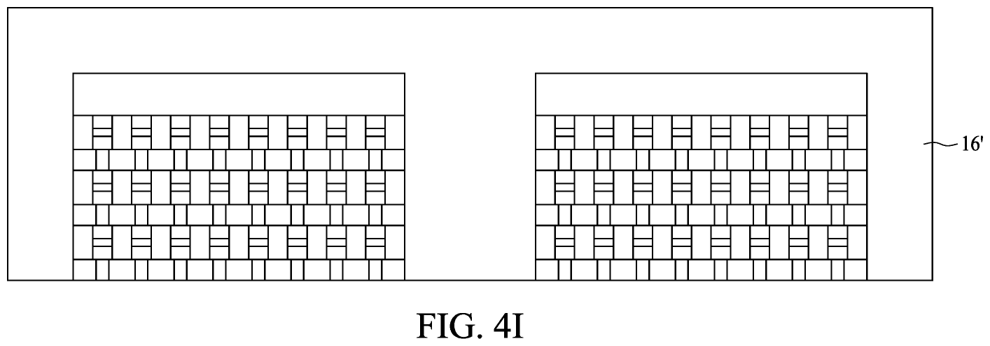

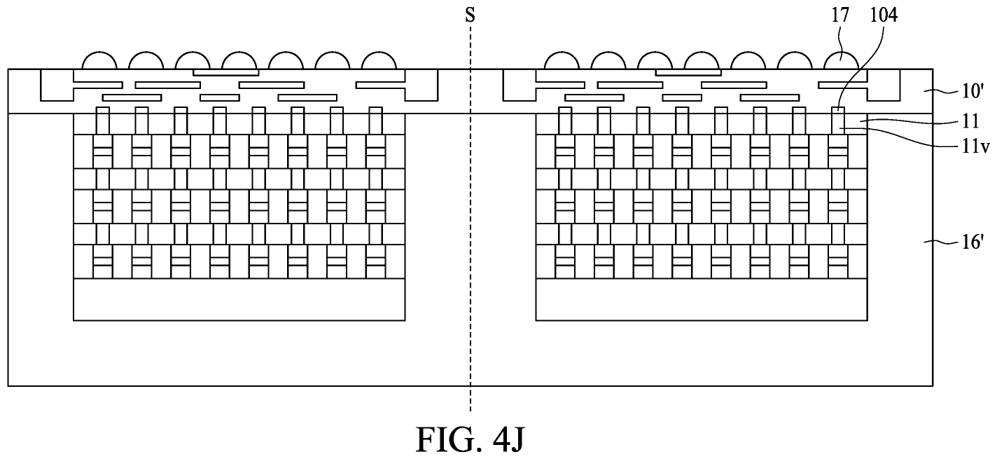

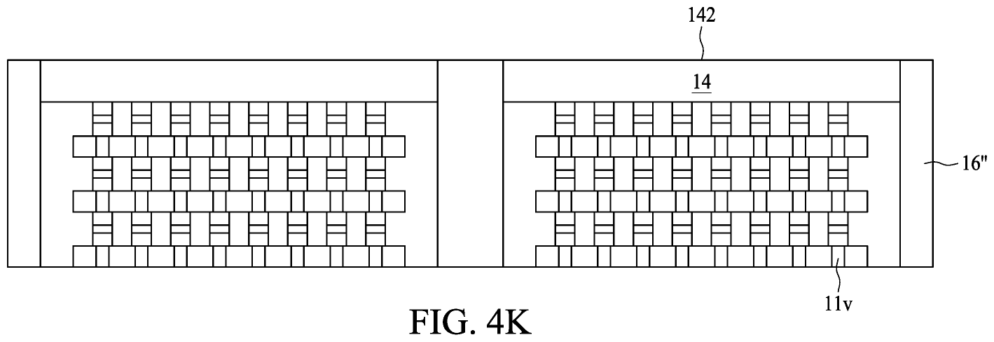

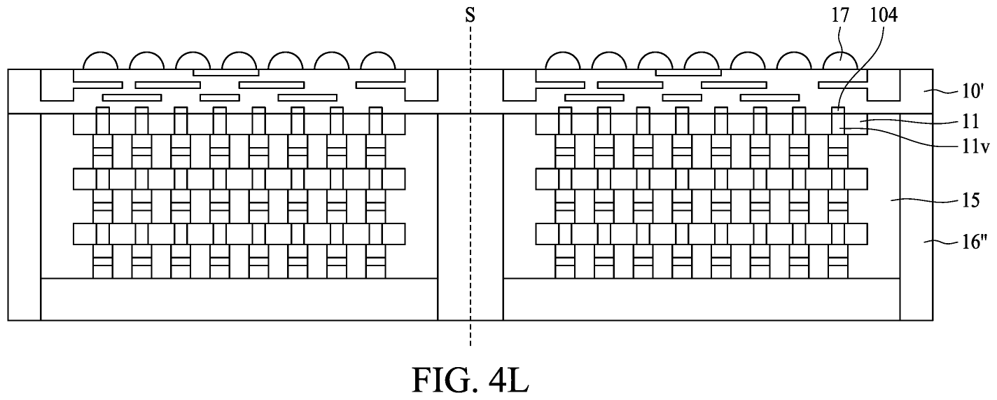

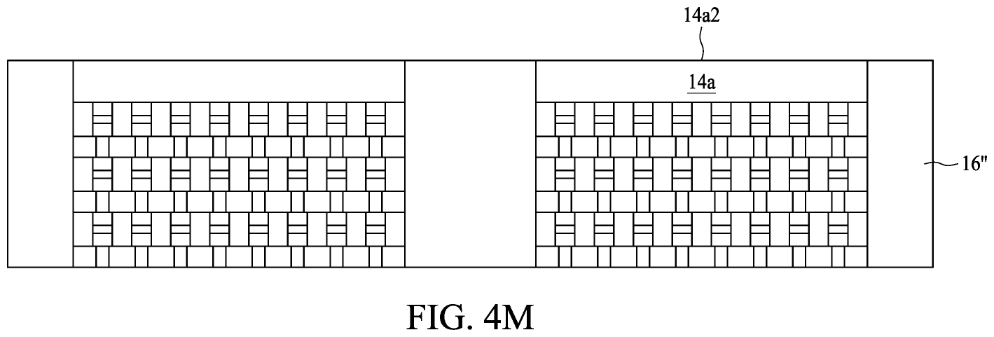

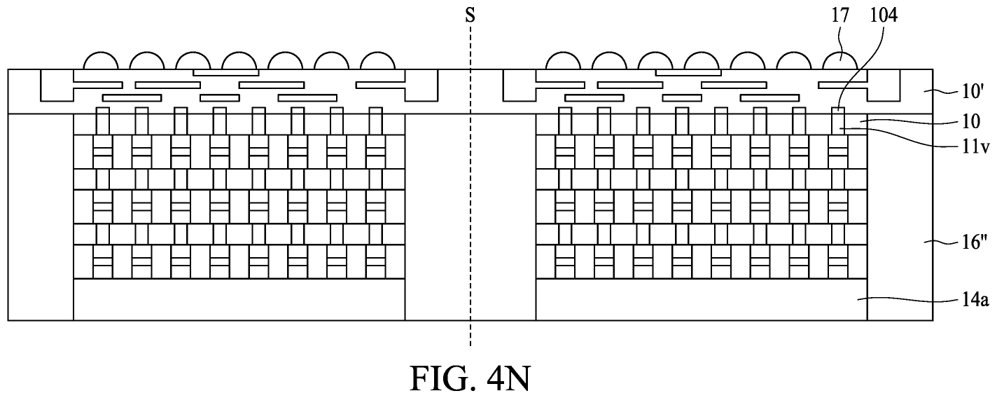

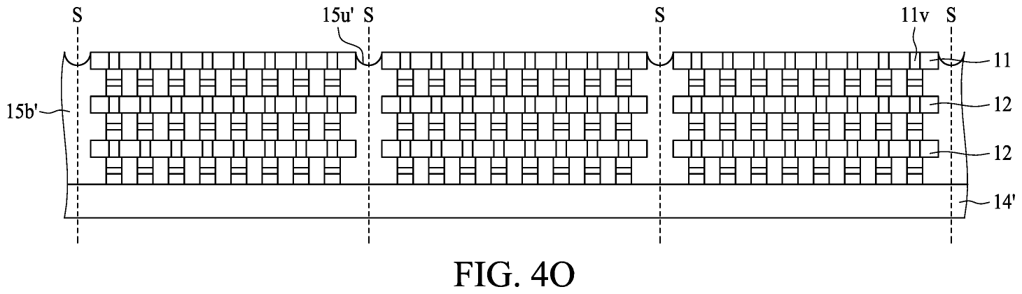

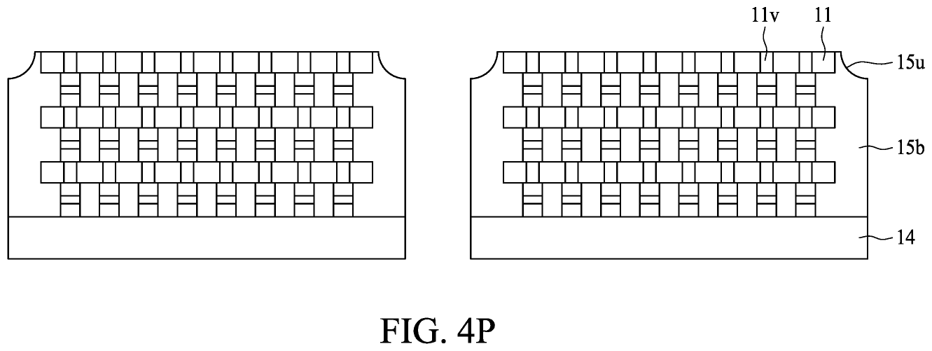

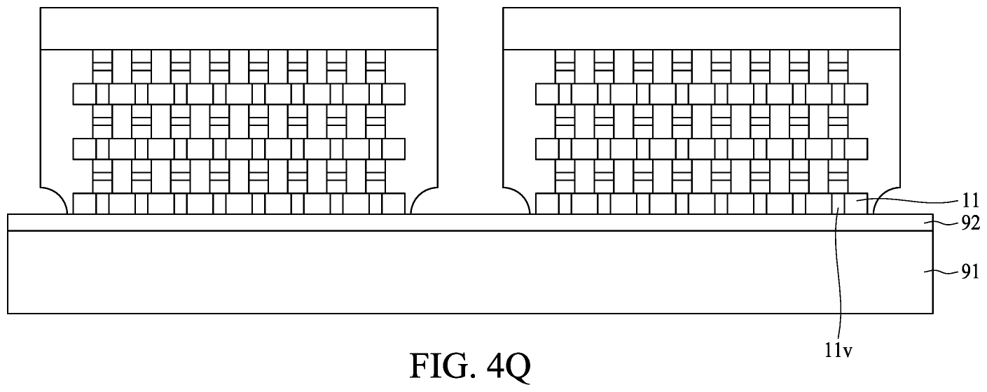

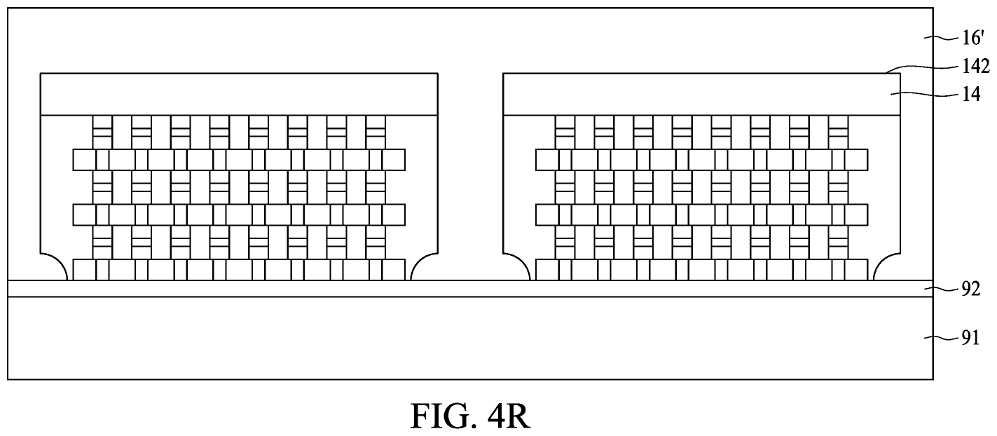

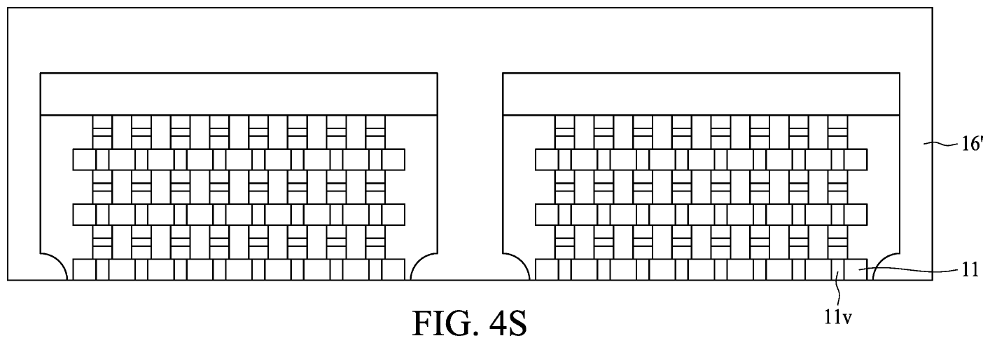

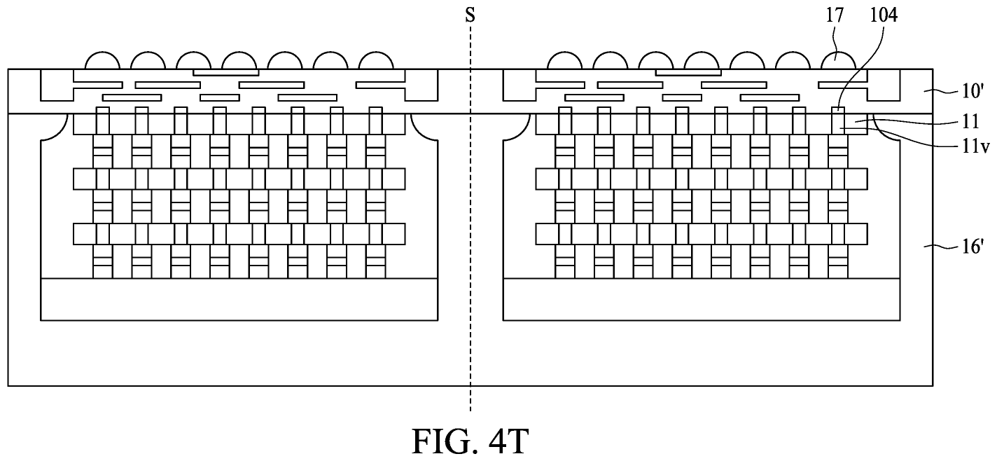

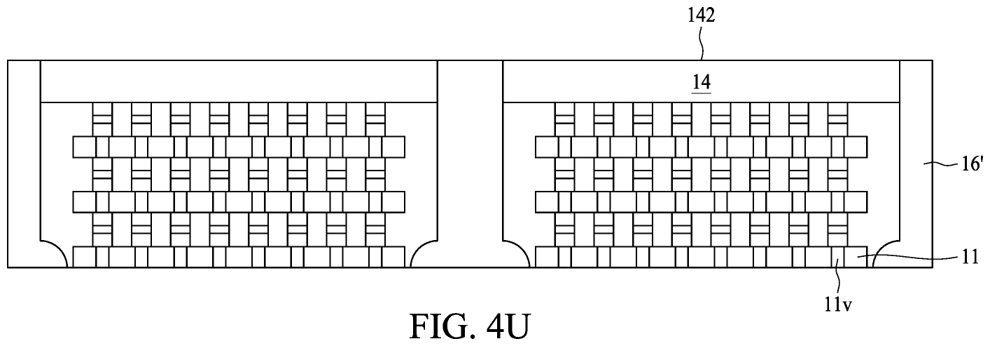

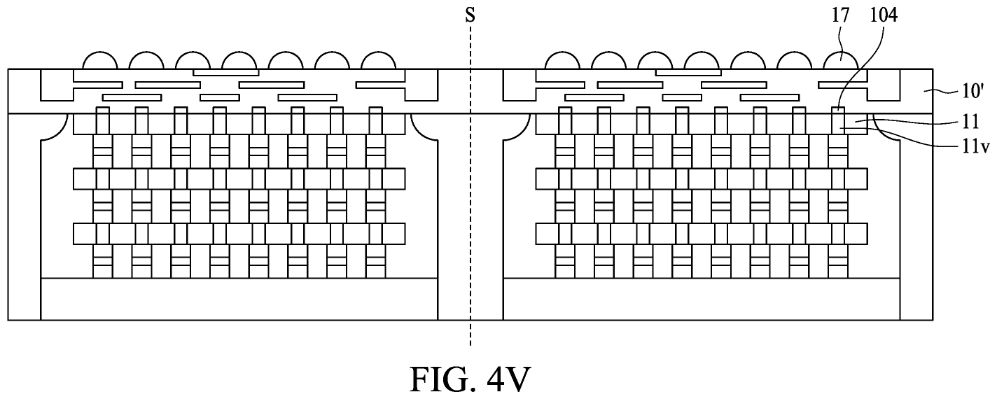

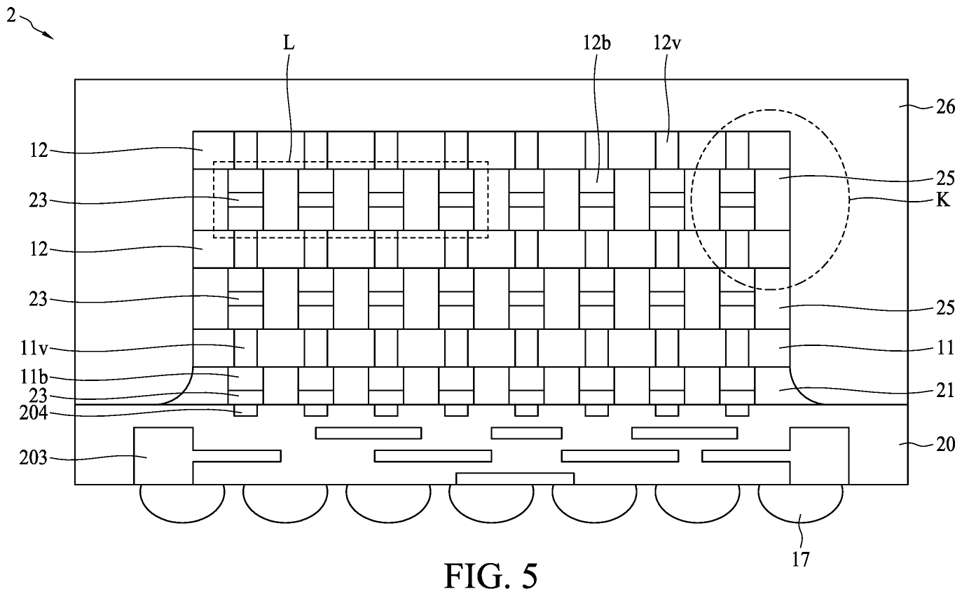

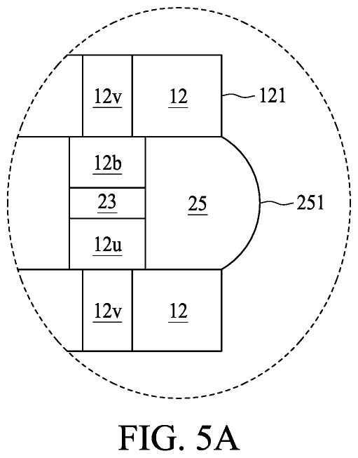

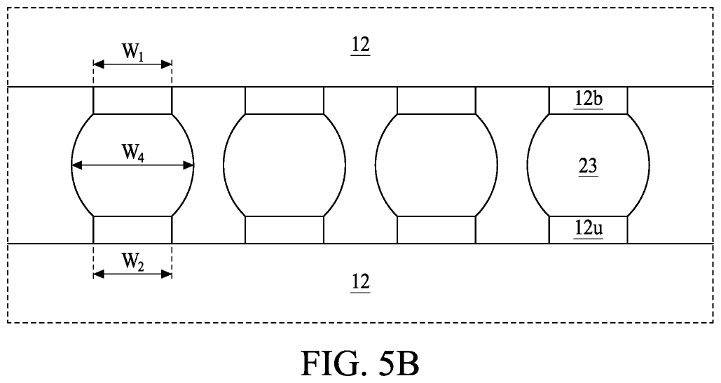

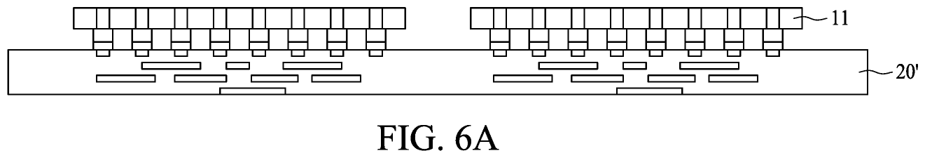

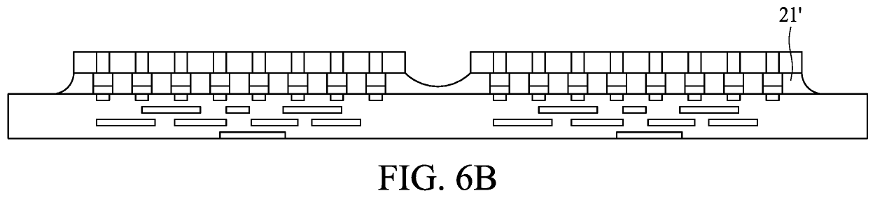

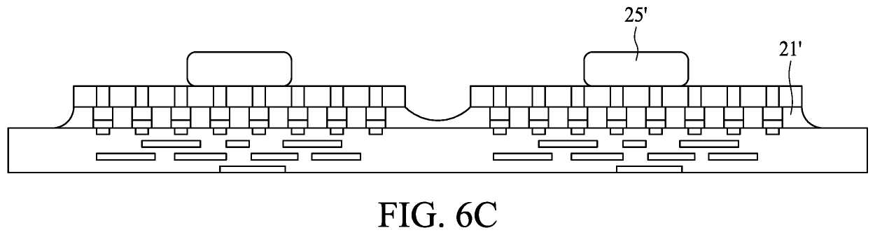

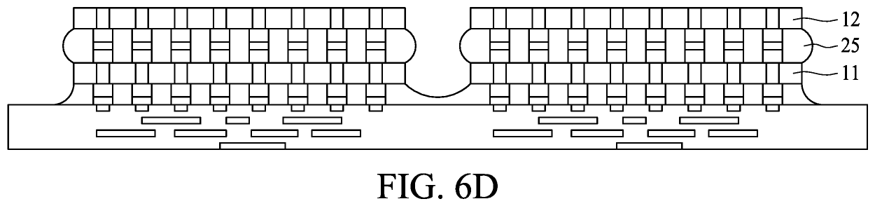

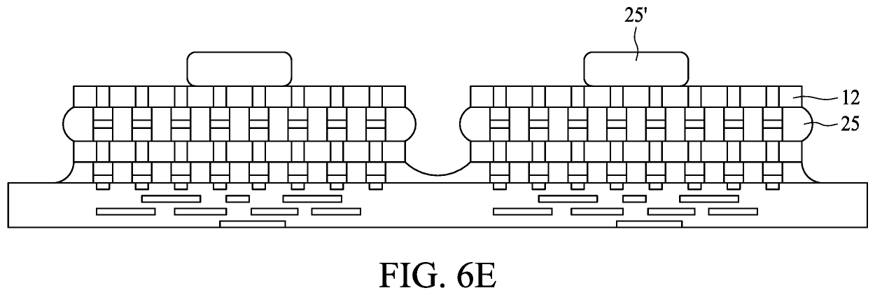

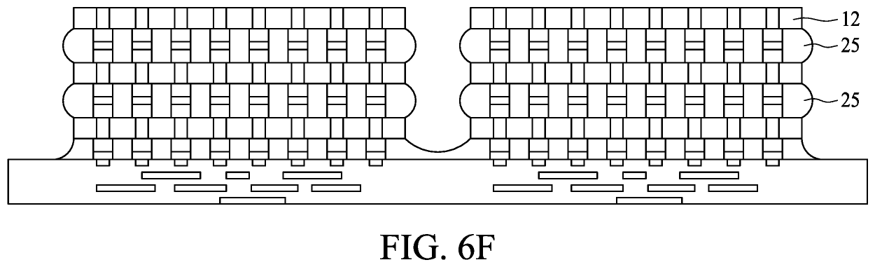

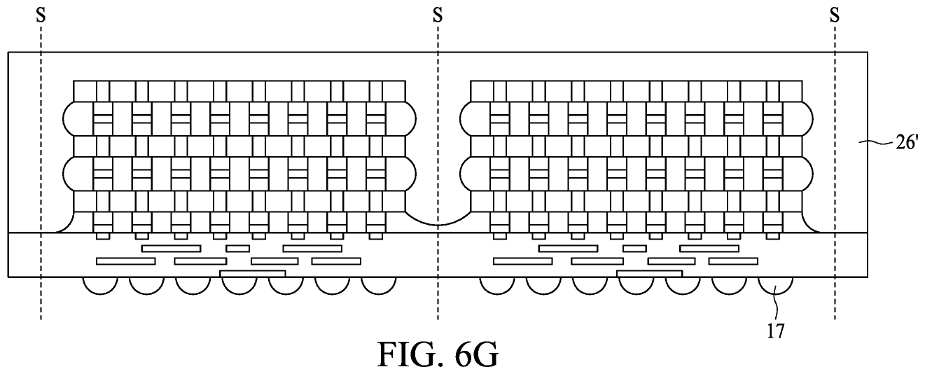

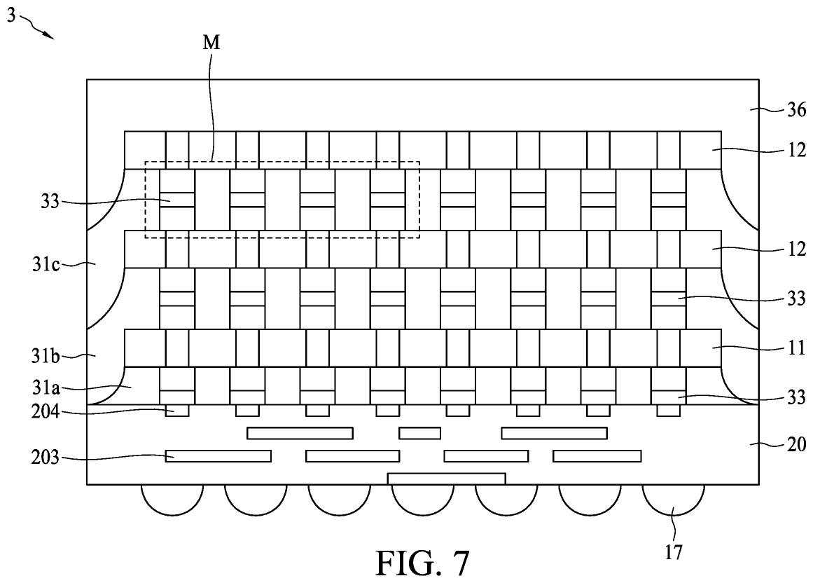

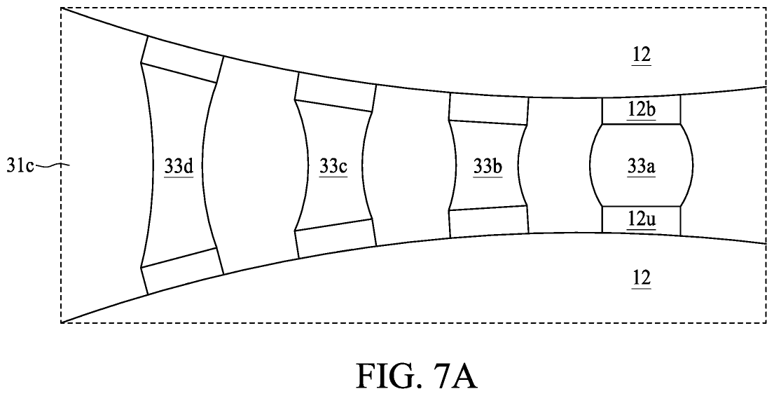

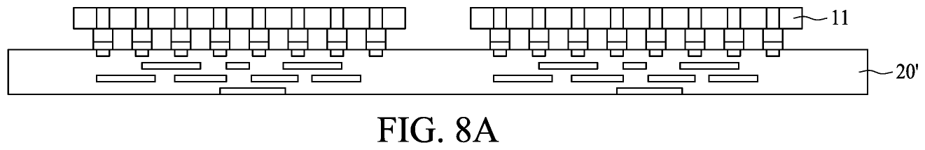

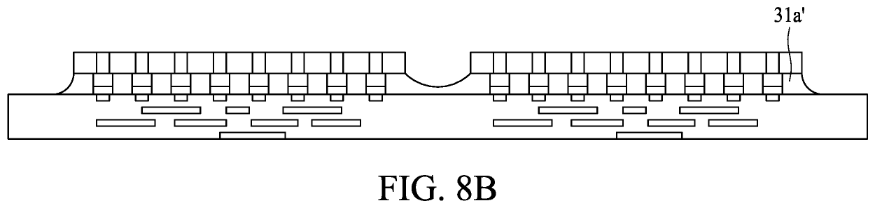

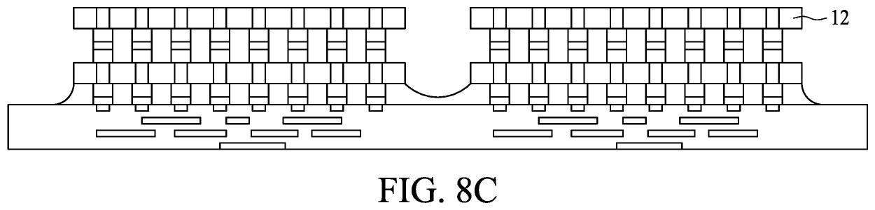

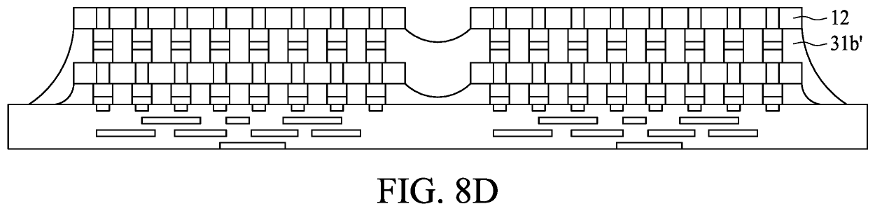

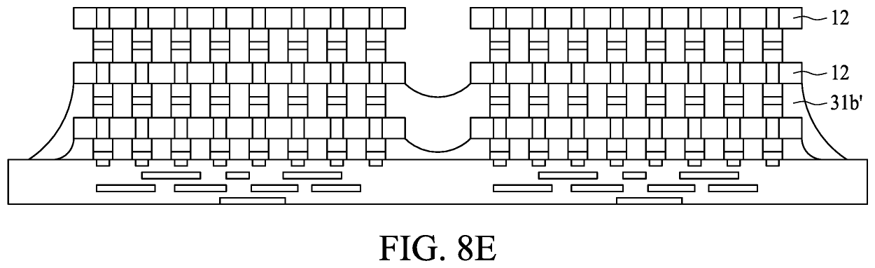

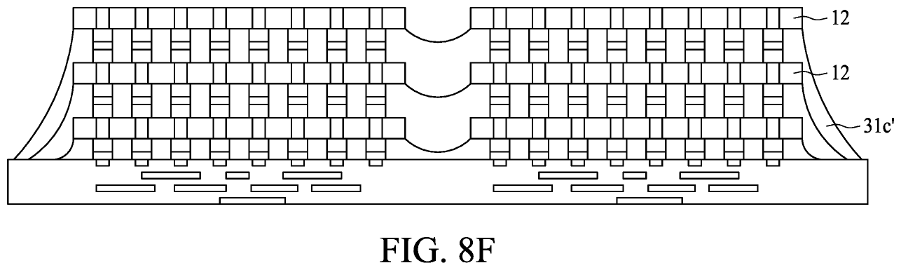

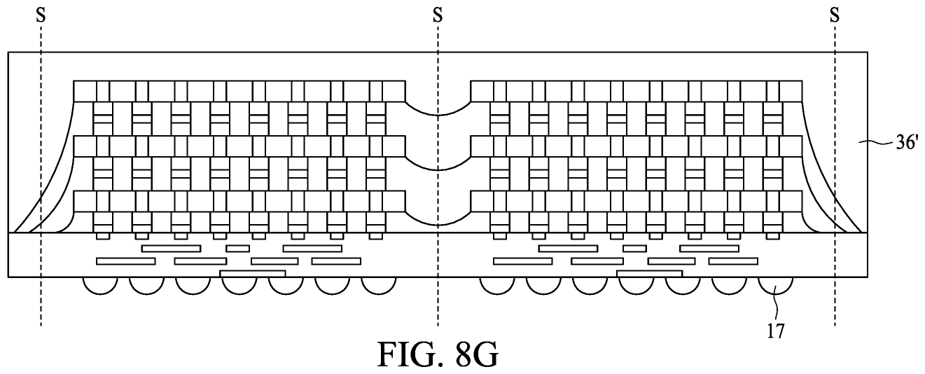

FIG. 3A is a cross-sectional view of another semiconductor device package in accordance with some embodiments of the present disclosure.

Referring to FIG. 3A, the semiconductor device package 1d can be similar to the semiconductor device package 1a as described and illustrated with reference to FIG. 1A, except that the semiconductor device 11 can be in direct with the redistribution layer 10, the interconnections 11b can be eliminated, and the insulation body 16 is replaced by an insulation body 16c.

The conductive via 11v can be in direct contact with the conductive contact 104.

The surface 142 can be covered by the insulation body 16c.

The insulation body 15 can encapsulate the semiconductor device 11. The insulation body 15 can encapsulate the semiconductor device 12. The insulation body 15 can encapsulate the semiconductor device 14. The insulation body 15 can encapsulate the conductive contact 14b. The insulation body 15 can encapsulate the interconnection 13. The insulation body 15 can encapsulate the conductive contact 12u. The insulation body 15 can encapsulate the conductive contact 12b. The insulation body 15 can encapsulate the conductive contact 11u.

The insulation body 15 can include a lateral surface 151. The lateral surface 151 of the insulation body 15 can be substantially coplanar with the lateral surface 143 of the semiconductor device 14.

The insulation body 15 can include insulation or dielectric material. The insulation body 15 can include resin (e.g. bismaleimide triazine resin (BT). The insulation body 15 can include fillers or particles (e.g. SiO2 particles) (not shown in FIG. 3A). The insulation body 15 can include epoxy. The insulation body 15 can include underfill material. The insulation body 15 can include molding compound (e.g. epoxy molding compound (EMC)) or encapsulation material.

The insulation body 16c can be similar to the insulation body 16 as described and illustrated with reference to FIG. 1A, except that the insulation body 16c may have a relatively great thickness, and the insulation body 16c may not be disposed between the semiconductor device 11 and the redistribution layer 10.

The insulation body 16c can encapsulate the semiconductor device 11. The insulation body 16c can encapsulate the insulation body 15. The insulation body 16c can encapsulate the semiconductor device 14. The surface 101 of the redistribution layer 10 can be in direct contact with the semiconductor device 11.

The insulation body 16c can surround the semiconductor device 11. The insulation body 16c can surround the semiconductor device 12. The insulation body 16c can surround the semiconductor device 14. The insulation body 16c can surround the insulation body 15. The insulation body 16c can be in direct contact with the insulation body 15.

The insulation body 16c can include insulation or dielectric material. The insulation body 16c can include fillers or particles (e.g. SiO2 particles) (not shown in FIG. 3A). The insulation body 16c can include epoxy. The insulation body 16c can include molding compound (e.g. epoxy molding compound (EMC)) or encapsulation material. The insulation body 16c can include material same or similar to the insulation body 15. The insulation body 16a can include material different from the insulation body 15.

The structure in the dotted circle E can be similar to the structure in the dotted circle A as shown in FIG. 1A.

FIG. 3B is a cross-sectional view of another semiconductor device package in accordance with some embodiments of the present disclosure.

Referring to FIG. 3B, the semiconductor device package 1e can be similar to the semiconductor device package 1d as described and illustrated with reference to FIG. 3A, except that the semiconductor device 14 is replaced by a semiconductor device 14a, the insulation body 15 is replaced by an insulation body 15a, and the insulation body 16c is replaced by an insulation body 16d.

The semiconductor device 14a can be similar to the semiconductor device 14 as described and illustrated with reference to FIG. 3A, except that the semiconductor device 14a may have a relatively less width than semiconductor device 14. A width of the semiconductor device 14a can be substantially same to the semiconductor device 11. A width of the semiconductor device 14a can be substantially same to the semiconductor device 12.

The semiconductor device 14a can include a surface 14a1, another surface 14a2 opposite the surface 14a1, and a lateral surface 14a3 extended from the surface 14al to the surface 14a2.

The surface 14a2 can be covered by the insulation body 16d.

The insulation body 15a can be similar to the insulation body 15 as described and illustrated with reference to FIG. 3A, except that the insulation body 15a may have a relatively less width than insulation body 15.

The insulation body 15a can encapsulate the semiconductor device 11. The insulation body 15a can encapsulate the semiconductor device 12. The insulation body 15a can encapsulate the semiconductor device 14a. The insulation body 15a can encapsulate the conductive contact 14b. The insulation body 15a can encapsulate the interconnection 13. The insulation body 15a can encapsulate the conductive contact 12u. The insulation body 15a can encapsulate the conductive contact 12b. The insulation body 15a can encapsulate the conductive contact 11u.

The insulation body 15a can include a lateral surface 15al. The lateral surface 15a1 of the insulation body 15a can be substantially coplanar with the lateral surface 14a3 of the semiconductor device 14a. The lateral surface 15a1 of the insulation body 15a can be substantially coplanar with a lateral surface of the semiconductor device 12 (not denoted in FIG. 3B). The lateral surface 15a1 of the insulation body 15a can be substantially coplanar with a lateral surface of the semiconductor device 11 (not denoted in FIG. 3B).

The insulation body 15a can include insulation or dielectric material. The insulation body 15a can include resin (e.g. bismaleimide triazine resin (BT). The insulation body 15a can include fillers or particles (e.g. SiO2 particles) (not shown in FIG. 3B). The insulation body 15a can include epoxy. The insulation body 15a can include underfill material. The insulation body 15a can include molding compound (e.g. epoxy molding compound (EMC)) or encapsulation material.

The insulation body 16d can be similar to the insulation body 16c as described and illustrated with reference to FIG. 3A, except that the insulation body 16d may have a relatively great volume in or around the periphery (e.g. a zone from the lateral surface 14a3 of the semiconductor device 14a to an edge of the insulation body 16d).

The insulation body 16d can encapsulate the semiconductor device 11. The insulation body 16d can encapsulate the insulation body 15a. The insulation body 16d can encapsulate the semiconductor device 14a.

The insulation body 16d can surround the semiconductor device 11. The insulation body 16d can surround the semiconductor device 12. The insulation body 16d can surround the semiconductor device 14a. The insulation body 16d can surround the insulation body 15a. The insulation body 16d can be in direct contact with the insulation body 15a.

The insulation body 16d can include insulation or dielectric material. The insulation body 16d can include fillers or particles (e.g. SiO2 particles) (not shown in FIG. 3B). The insulation body 16d can include epoxy. The insulation body 16d can include molding compound (e.g. epoxy molding compound (EMC)) or encapsulation material. The insulation body 16d can include material same or similar to the insulation body 15a. The insulation body 16d can include material different from the insulation body 15a.

The structure in the dotted circle F can be similar to the structure in the dotted circle A as shown in FIG. 1A.

FIG. 3C is a cross-sectional view of another semiconductor device package in accordance with some embodiments of the present disclosure.

Referring to FIG. 3C, the semiconductor device package if can be similar to the semiconductor device package 1d as described and illustrated with reference to FIG. 3A, except that the insulation body 16c is replaced by an insulation body 16e.

The insulation body 16e can be similar to the insulation body 16c as described and illustrated with reference to FIG. 3A, except that part of the insulation body 16e can be removed to expose the surface 142 of the semiconductor device 14.

The structure in the dotted circle G can be similar to the structure in the dotted circle A as shown in FIG. 1A.

FIG. 3D is a cross-sectional view of another semiconductor device package in accordance with some embodiments of the present disclosure.

Referring to FIG. 3D, the semiconductor device package 1g can be similar to the semiconductor device package 1e as described and illustrated with reference to FIG. 3B, except that the insulation body 16d is replaced by an insulation body 16f.

The insulation body 16f can be similar to the insulation body 16d as described and illustrated with reference to FIG. 3B, except that part of the insulation body 16d can be removed to expose the surface 14a2 of the semiconductor device 14a.

The structure in the dotted circle F can be similar to the structure in the dotted circle A as shown in FIG. 1A.

FIG. 3E is a cross-sectional view of another semiconductor device package in accordance with some embodiments of the present disclosure.

Referring to FIG. 3E, the semiconductor device package 1h can be similar to the semiconductor device package 1c as described and illustrated with reference to FIG. 1C, except that the semiconductor device 11 can be in direct with the redistribution layer 10, the interconnections 11b can be eliminated, and the insulation body 16b is replaced by an insulation body 16g.

The conductive via 11v can be in direct contact with the conductive contact 104.

The surface 142 can be covered by the insulation body 16g.

The insulation body 15b can encapsulate the semiconductor device 11. The insulation body 15b can encapsulate the semiconductor device 12. The insulation body 15b can encapsulate the semiconductor device 14. The insulation body 15b can encapsulate the conductive contact 14b. The insulation body 15b can encapsulate the interconnection 13. The insulation body 15b can encapsulate the conductive contact 12u. The insulation body 15b can encapsulate the conductive contact 12b. The insulation body 15b can encapsulate the conductive contact 11u.

The insulation body 15b can include a lateral surface 15b1. The lateral surface 15b1 of the insulation body 15b can be substantially coplanar with the lateral surface 143 of the semiconductor device 14.

The insulation body 15b can include insulation or dielectric material. The insulation body 15b can include resin (e.g. bismaleimide triazine resin (BT). The insulation body 15b can include fillers or particles (e.g. SiO2 particles) (not shown in FIG. 3E). The insulation body 15b can include epoxy. The insulation body 15b can include underfill material. The insulation body 15b can include molding compound (e.g. epoxy molding compound (EMC)) or encapsulation material.

The insulation body 16g can be similar to the insulation body 16b as described and illustrated with reference to FIG. 1C, except that the insulation body 16g may have a relatively great thickness, and the insulation body 16g may not be disposed between the semiconductor device 11 and the redistribution layer 10.

The insulation body 16g can encapsulate the semiconductor device 11. The insulation body 16g can encapsulate the insulation body 15b. The insulation body 16c can encapsulate the semiconductor device 14. The surface 101 of the redistribution layer 10 can be in direct contact with the semiconductor device 11.

The insulation body 16g can surround the semiconductor device 11. The insulation body 16g can surround the semiconductor device 12. The insulation body 16g can surround the semiconductor device 14. The insulation body 16g can surround the insulation body 15b. The insulation body 16g can be in direct contact with the insulation body 15b.

The insulation body 16g can include insulation or dielectric material. The insulation body 16g can include fillers or particles (e.g. SiO2 particles) (not shown in FIG. 3E). The insulation body 16g can include epoxy. The insulation body 16g can include molding compound (e.g. epoxy molding compound (EMC)) or encapsulation material. The insulation body 16g can include material same or similar to the insulation body 15b. The insulation body 16g can include material different from the insulation body 15b.

The structure in the dotted circle I can be similar to the structure in the dotted circle A as shown in FIG. 1A.

FIG. 3F is a cross-sectional view of another semiconductor device package in accordance with some embodiments of the present disclosure.

Referring to FIG. 3F, the semiconductor device package 1i can be similar to the semiconductor device package 1h as described and illustrated with reference to FIG. 3E, except that the insulation body 16g is replaced by an insulation body 16h.

The insulation body 16h can be similar to the insulation body 16g as described and illustrated with reference to FIG. 3EB, except that part of the insulation body 16g can be removed to expose the surface 142 of the semiconductor device 14.

The structure in the dotted circle J can be similar to the structure in the dotted circle A as shown in FIG. 1A.

FIG. 2A, FIG. 2B, FIG. 2C, FIG. 4A, FIG. 4B, FIG. 4C, FIG. 4D and FIG. 4E illustrate various stages of another method for manufacturing a semiconductor device package accordance with some embodiments of the subject application.

Referring to FIG. 4A, a cutting operation or a singulation operation may be performed along the scribe lines S as shown in FIG. 2C to form some stacked structures as shown in FIG. 4A. The cutting operation or singulation operation can be performed by a tool or knife of a relatively less width.

Referring to FIG. 4B, the stacked structures as shown in FIG. 4A can be disposed on a carrier 91. The stacked structures as shown in FIG. 4A can be disposed on a release layer 92 provided on the carrier 91.

Referring to FIG. 4C, insulation material 16′ can be formed on the release layer 92 to encapsulate the stacked structures as shown in FIG. 4B.

Referring to FIG. 4D, the release layer 91 and the carrier 92 can be removed.

Referring to FIG. 4E, a redistribution layer 10′ can be formed on the structure as shown in FIG. 4D. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4E to form some semiconductor device packages 1d described and illustrated with reference to FIG. 3A.

FIG. 2A, FIG. 2B, FIG. 2C, FIG. 4F, FIG. 4G, FIG. 4H, FIG. 4I and FIG. 4J illustrate various stages of another method for manufacturing a semiconductor device package accordance with some embodiments of the subject application.

Referring to FIG. 4F, a cutting operation or a singulation operation may be performed along the scribe lines S as shown in FIG. 2C to form some stacked structures as shown in FIG. 4F. The cutting operation or singulation operation can be performed by a tool or knife of a relatively great width.

Referring to FIG. 4G, the stacked structures as shown in FIG. 4F can be disposed on a carrier 91. The stacked structures as shown in FIG. 4F can be disposed on a release layer 92 provided on the carrier 91.

Referring to FIG. 4H, insulation material 16′ can be formed on the release layer 92 to encapsulate the stacked structures as shown in FIG. 4G.

Referring to FIG. 4, the release layer 91 and the carrier 92 can be removed.

Referring to FIG. 4J, a redistribution layer 10′ can be formed on the structure as shown in FIG. 4I. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4J to form some semiconductor device packages 1e described and illustrated with reference to FIG. 3B.

FIG. 2A, FIG. 2B, FIG. 2C, FIG. 4A, FIG. 4B, FIG. 4C, FIG. 4K and FIG. 4L illustrate various stages of another method for manufacturing a semiconductor device package accordance with some embodiments of the subject application.

Referring to FIG. 4K, a portion of the insulation material 16′ can be removed to expose the semiconductor device 14. A portion of the insulation material 16′ can be removed to expose a surface 142 of the semiconductor device 14. A portion of the insulation material 16′ can be removed to form insulation material 16″. The release layer 91 and the carrier 92 can be removed.

Referring to FIG. 4L, a redistribution layer 10′ can be formed on the structure as shown in FIG. 4K. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4L to form some semiconductor device packages if described and illustrated with reference to FIG. 3C.

FIG. 2A, FIG. 2B, FIG. 2C, FIG. 4F, FIG. 4G, FIG. 4H, FIG. 4M and FIG. 4N illustrate various stages of another method for manufacturing a semiconductor device package accordance with some embodiments of the subject application.

Referring to FIG. 4M, a portion of the insulation material 16′ can be removed to expose the semiconductor device 14a. A portion of the insulation material 16′ can be removed to expose a surface 14a2 of the semiconductor device 14a. A portion of the insulation material 16′ can be removed to form insulation material 16″. The release layer 91 and the carrier 92 can be removed.

Referring to FIG. 4N, a redistribution layer 10′ can be formed on the structure as shown in FIG. 4M. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4N to form some semiconductor device packages 1g described and illustrated with reference to FIG. 3D.

FIG. 2A, FIG. 2B, FIG. 4O, FIG. 4P, FIG. 4Q, FIG. 4R, FIG. 4S and FIG. 4T illustrate various stages of another method for manufacturing a semiconductor device package accordance with some embodiments of the subject application.

Referring to FIG. 4O, some other semiconductor devices 12 can be attached, bonded or stacked to the semiconductor devices 12 as shown in FIG. 2B, by LAB technique or other suitable technique(s). Some semiconductor devices 11 can be attached, bonded or stacked to the semiconductor devices 12 by LAB technique or other suitable technique(s).

An insulation material 15b′ may be formed to encapsulate the stacked structures. The insulation material 15b′ can be formed by dispensing technique or other suitable technique(s). A concave surface 15u′ can be formed in the operation as shown in FIG. 4O.

Referring to FIG. 4P, a cutting operation or a singulation operation may be performed along the scribe lines S as shown in FIG. 4O to form some stacked structures as shown in FIG. 4P.

Referring to FIG. 4Q, the stacked structures as shown in FIG. 4P can be disposed on a carrier 91. The stacked structures as shown in FIG. 2R can be disposed on a release layer 92 provided on the carrier 91.

Referring to FIG. 4R, insulation material 16′ can be formed on the release layer 92 to encapsulate the stacked structures as shown in FIG. 4Q.

Referring to FIG. 4S, the release layer 91 and the carrier 92 can be removed.

Referring to FIG. 4T, a redistribution layer 10′ can be formed on the structure as shown in FIG. 4S. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4T to form some semiconductor device packages 1h described and illustrated with reference to FIG. 3E.

FIG. 2A, FIG. 2B, FIG. 4O, FIG. 4P, FIG. 4Q, FIG. 4R, FIG. 4U and FIG. 4V illustrate various stages of another method for manufacturing a semiconductor device package accordance with some embodiments of the subject application.

Referring to FIG. 4U, a portion of the insulation material 16′ can be removed to expose the semiconductor device 14. A portion of the insulation material 16′ can be removed to expose a surface 142 of the semiconductor device 14. A portion of the insulation material 16′ can be removed to form insulation material 16″. The release layer 91 and the carrier 92 can be removed.

Referring to FIG. 4V, a redistribution layer 10′ can be formed on the structure as shown in FIG. 4U. The conductive contact 104 can be electrically connected to the conductive via 11v. The conductive contact 104 can be in direct contact with the conductive via 11v. The redistribution layer 10′ can be in direct contact with the semiconductor device 10.

Some connection elements 17 may be formed on the redistribution layer 10′. The connection elements 17 can be electrically connected to redistribution layer 10′. A cutting operation or a singulation operation may be performed along the scribe lines S as shown in FIG. 4N to form some semiconductor device packages 1i described and illustrated with reference to FIG. 3F.

The semiconductor device packages as shown in FIG. 1A, FIG. 1B, FIG. 1C, FIG. 3A, FIG. 3B, FIG. 3C, FIG. 3D, FIG. 3E and FIG. 3F can be manufactured in accordance with methods as discussed above. The stacked structure of the semiconductor devices can be formed by LAB technique as described above. The LAB technique, which may consume relatively less time in stacking or bonding the semiconductor devices (e.g. relatively better self-alignment of the upper die and the lower die, relatively less thermal cycle time), may facilitate manufacture (e.g. unit per hour (UPH) can be improved). The LAB technique, which may mitigate warpage issue, may improve reliability of the semiconductor device packages.

Underfill material, which can be relatively cost effective, can be used as insulation body 15, 15a or 15b. The semiconductor device packages as shown in FIG. 1A, FIG. 1B, FIG. 1C, FIG. 3A, FIG. 3B, FIG. 3C, FIG. 3D, FIG. 3E and FIG. 3F can be manufactured from the top semiconductor device (e.g. the wafer 14′, which can include semiconductor device 14 or 14a), the redistribution layer 10 can be formed subsequent to forming the insulation body 15, 15a or 15b to avoid contamination.

FIG. 5 is a cross-sectional view of another semiconductor device package in accordance with some embodiments of the present disclosure.

Referring to FIG. 5, a semiconductor device package 2 can include a substrate 20, a stack of semiconductor devices 11 and 12, interconnections 23, insulation body 21, insulation body 25, insulation body 26 and connection elements 17.

The substrate 20 can include circuitry 203. The substrate 20 can include conductive contacts 204.

The substrate 20 can have a pitch equal to or greater than approximately 10 μm. The substrate 20 can have a line width/space equal to or greater than approximately 10/10 μm.

FIG. 5A is an enlarged view of structure in dotted circle K as shown in FIG. 5.

Referring to FIG. 5A, the insulation body 25 can have a protrusion 251. The insulation body 25 can have a surface 251 over the lateral surface 121 of the semiconductor device 12. The insulation body 25 can have a convex surface 251 over the lateral surface 121 of the semiconductor device 12. The insulation body 25 can have a curve surface 251 over the lateral surface 121 of the semiconductor device 12.

FIG. 5B is an enlarged view of structure in dotted box L as shown in FIG. 5.

Referring to FIG. 5B, the conductive contact 12b of the semiconductor device 12 may have a width W₁, the conductive contact 12u of the semiconductor device 12 may have a width W₂, and the interconnection 23 can have a maximum width W₄.

The width W₄ can be substantially greater than the width W₁. The width W₄ can be substantially greater than the width W₂. The width W₄ can be substantially greater than 1.2 times the width W₁. The width W₄ can be substantially greater than 1.2 times the width W₂. The width W₄ can be substantially greater than 1.5 times the width W₁. The width W₄ can be substantially greater than 1.5 times the width W₂.

The interconnection 23 can be formed by thermal compression bonding technique.

FIG. 6A, FIG. 6B, FIG. 6C, FIG. 6D, FIG. 6E, FIG. 6F and FIG. 6G illustrate various stages of another method for manufacturing a semiconductor device package accordance with some embodiments of the subject application.

Referring to FIG. 6A, a strip or panel of substrates 20′ can be provided. The strip or panel 20′ can include some substrates 20.

Some semiconductor devices 11 can be attached or bonded to the strip or panel 20′ by flip-chip bond technique or TCB technique.

Referring to FIG. 6B, insulation material 21′ can be formed between the strip or panel 20′ and the semiconductor devices 11.

Referring to FIG. 6C, insulation material 25′ can be disposed on the semiconductor devices 11. The insulation material 25′ may include a non-conductive film (NCF), a non-conductive paste (NCP), an anisotropic conductive film (ACF) or an anisotropic conductive paste (ACP).

Referring to FIG. 6D, some semiconductor devices 12 can be bonded, stacked, or attached to the semiconductor devices 11 by TCB technique. The insulation material 25′ can be pressed to form an insulation body 25, which protrudes over an edge of the semiconductor device 11. The insulation material 25′ can be pressed to form an insulation body 25, which protrudes over an edge of the semiconductor device 12.

Referring to FIG. 6E, insulation material 25′ can be disposed on the semiconductor devices 12. The insulation material 25′ may include a non-conductive film (NCF), a non-conductive paste (NCP), an anisotropic conductive film (ACF) or an anisotropic conductive paste (ACP).

Referring to FIG. 6F, another semiconductor devices 12 can be bonded, stacked, or attached to the semiconductor devices 12 by TCB technique. The insulation material 25′ can be pressed to form an insulation body 25, which protrudes over an edge of the semiconductor device 12.

Flip-chip bonding technique (or mass reflow technique) may be used to form the stacked structures as shown in FIG. 6F, however, Crack or damage may easily be observed on the interconnection 23 (especially the relatively lower interconnections 23 which experience relatively more thermal cycles, and therefore have relatively great fragile intermetallic compound (IMC)). Moreover, relatively more thermal cycles can result in warpage of the stacked structure, which may form a structure as shown in FIG. 7A. The interconnections as shown in FIG. 7A can be vulnerable, which may cause reliability issue.

The use of TCB technique to form the stacked structures as shown in FIG. 6F can mitigate or avoid the crack issue of the interconnection 23. However, TCB technique may consume relatively great time in heating, alignment, etc., which may adversely affect manufacture (e.g. unit per hour (UPH)). Moreover, the NCF, NCP, ACF or ACP, which is used together with the TCB technique, may be relatively expensive. Moreover, TCB technique may form relatively wide interconnections 23 (e.g. the interconnections 23 as shown in FIG. 5B), which may adversely affect miniaturization of the semiconductor device package 2.

Referring to FIG. 6G, insulation material 26′ can be formed to encapsulate the stacked structure on the strip or panel 20′ as shown in FIG. 6F. Some conductive elements 17 can be formed on the strip or panel 20′.

A cutting operation or a singulation operation may be performed along the scribe lines S as shown in FIG. 6G to form some semiconductor device packages 2 described and illustrated with reference to FIG. 5.

FIG. 7 is a cross-sectional view of another semiconductor device package in accordance with some embodiments of the present disclosure.

Referring to FIG. 7, a semiconductor device package 3 can include a substrate 20, a stack of semiconductor devices 11 and 12, interconnections 33, insulation body 31a, insulation body 31b, insulation body 31c and connection elements 17.

FIG. 7A is an enlarged view of structure in dotted box M as shown in FIG. 7.

Referring to FIG. 7A, the semiconductor devices 12 may warp. For example, an edge of the upper semiconductor devices 12 can be bent or warped upward. For example, an edge of the lower semiconductor devices 12 can be bent or warped downward. The interconnections 33 can include an interconnection 33a, which can be relatively adjacent to the center of the semiconductor device 12. The interconnections 33 can include an interconnection 33b, which can be relatively adjacent to the edge of the semiconductor device 12 as compared to the interconnection 33a. The interconnections 33 can include an interconnection 33c, which can be relatively adjacent to the edge of the semiconductor device 12 as compared to the interconnection 33b. The interconnections 33 can include an interconnection 33d, which can be relatively adjacent to the edge of the semiconductor device 12 as compared to the interconnection 33c.

The interconnection 33b can have a neck (not denoted in FIG. 7A). The interconnection 33c can have a neck (not denoted in FIG. 7A). The interconnection 33d can have a neck (not denoted in FIG. 7A). The structure as shown in FIG. 7A may be caused by mass reflow technique or flip-chip bond technique.

It is contemplated the structure in dotted box M as shown in FIG. 7 can have an enlarged view as described and illustrated with reference to FIG. 5B, which can be caused by TCB technique.

FIG. 8A, FIG. 8B, FIG. 8C, FIG. 8D, FIG. 8E, FIG. 8F and FIG. 8G illustrate various stages of another method for manufacturing a semiconductor device package accordance with some embodiments of the subject application.

Referring to FIG. 8A, a strip or panel of substrates 20′ can be provided. The strip or panel 20′ can include some substrates 20.

Some semiconductor devices 11 can be attached or bonded to the strip or panel 20′ by flip-chip bond technique or TCB technique.

Referring to FIG. 8B, insulation material 31a′ can be formed between the strip or panel 20′ and the semiconductor devices 11.

Referring to FIG. 8C, some semiconductor devices 12 can be bonded, stacked, or attached to the semiconductor devices 11 by TCB technique, mass reflow technique, flip-chip bond technique or other suitable technique(s).

Referring to FIG. 8D, insulation material 31b′ can be formed between the semiconductor devices 11 and the semiconductor devices 12. The insulation material 31b′ can be formed on the strip or panel 20′. The insulation material 31b′ can be in direct contact with the strip or panel 20′. The insulation material 31b′ can be formed on the insulation material 31a′. The insulation material 31b′ can be in direct contact with the insulation material 31a′.

Referring to FIG. 8E, some other semiconductor devices 12 can be bonded, stacked, or attached to the semiconductor devices 12 by TCB technique, mass reflow technique, flip-chip bond technique or other suitable technique(s).

Referring to FIG. 8F, insulation material 31c′ can be formed between the semiconductor devices 12 and the semiconductor devices 12. The insulation material 31c′ can be formed on the strip or panel 20′. The insulation material 31c′ can be in direct contact with the strip or panel 20′. The insulation material 31c′ can be formed on the insulation material 31b′. The insulation material 31c′ can be in direct contact with the insulation material 31b′.

Flip-chip bonding technique (or mass reflow technique) may be used to form the stacked structures as shown in FIG. 8F, however, Crack or damage may easily be observed on the interconnection 33 (especially the relatively lower interconnections 33 which experience relatively more thermal cycles, and therefore have relatively great fragile intermetallic compound (IMC)). Moreover, relatively more thermal cycles can result in warpage of the stacked structure, which may form a structure as shown in FIG. 7A. The interconnections as shown in FIG. 7A can be vulnerable, which may cause reliability issue.

The use of TCB technique to form the stacked structures as shown in FIG. 8F can mitigate or avoid the crack issue of the interconnection 33. However, TCB technique may consume relatively great time in heating, alignment, etc., which may adversely affect manufacture (e.g. unit per hour (UPH)). Moreover, TCB technique may form relatively wide interconnections 33 (which can be similar to, e.g. the interconnections 23 as shown in FIG. 5B), which may adversely affect miniaturization of the semiconductor device package 4. Further, forming the insulation material 31a′, 31b′ and 31c′ may inevitably contaminate the strip or panel 20′, which can adversely affect reliability of the semiconductor device package 3. Delamination or crack can occur on an interface between the insulation material 31a′ and the insulation material 31b′ during manufacture (e.g. when performing cutting operation or singulation operation as shown in FIG. 8G). Delamination or crack can occur on an interface between the insulation material 31b′ and the insulation material 31c′ during manufacture (e.g. when performing cutting operation or singulation operation as shown in FIG. 8G). Delamination or crack can occur on an interface between the insulation material 31c′ and the insulation material 36′ during manufacture (e.g. when performing cutting operation or singulation operation as shown in FIG. 8G).

Referring to FIG. 8G, insulation material 36′ can be formed to encapsulate the stacked structure on the strip or panel 20′ as shown in FIG. 8F. Some conductive elements 17 can be formed on the strip or panel 20′.

A cutting operation or singulation operation may be performed along the scribe lines S as shown in FIG. 8G to form some semiconductor device packages 3 described and illustrated with reference to FIG. 7.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately”, “substantially”, “substantial” and “about” are used to describe and account for small variations. When used in conduction with an event or circumstance, the terms can refer to instances in which the event of circumstance occurs precisely as well as instances in which the event or circumstance occurs to a close approximation. As sued herein with respect to ta given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor device package, comprising:
a redistribution layer;
a first semiconductor device disposed on the redistribution layer;
a second semiconductor device stacked on the first semiconductor device;
a first insulation body disposed between the first semiconductor device and the second semiconductor device, the first insulation body having a number of first particles; and
a second insulation body encapsulating the first insulation body and having a number of second particles,
wherein one of the number of first particles has a flat surface.

2. The semiconductor device package of claim 1, wherein the flat surface of the one of the number of first particles is substantially coplanar with a first surface of the first insulation body.

3. The semiconductor device package of claim 1, wherein the flat surface of the one of the number of first particles is in direct contact with the second insulation body.

4. The semiconductor device package of claim 1, wherein a portion of the second insulation body is disposed between the redistribution layer and the first semiconductor device.

5. The semiconductor device package of claim 1, wherein the second semiconductor device has a width greater than the first semiconductor device.

6. The semiconductor device package of claim 1, wherein a first surface of the second semiconductor device is exposed from the second insulation body.

7. The semiconductor device package of claim 1, wherein the first insulation body has a concave surface.

8. The semiconductor device package of claim 7, wherein the concave surface is adjacent to the first semiconductor device.

9. The semiconductor device package of claim 7, wherein the second insulation body has a convex surface engaged with the concave surface of the first insulation body.

10. The semiconductor device package of claim 1, wherein, the first semiconductor device has a first conductive contact having a first width, and the second semiconductor device has a first conductive contact, and wherein the semiconductor device package further comprises an interconnection between the first conductive contact of the first semiconductor device and the first conductive contact of the second semiconductor device, and the interconnection has a maximum width, and wherein the maximum width of the interconnection is substantially the same with the first width.

11. The semiconductor device package of claim 10, wherein the maximum width of the interconnection is substantially equal to or less than 1.2 times the first width.

12. The semiconductor device package of claim 1, wherein an average size of the number of first particles is substantially less than the number of second particles.

13. A semiconductor device package, comprising:
a redistribution layer;
a first semiconductor device disposed on the redistribution layer and having a first lateral surface;
a second semiconductor device stacked on the first semiconductor device and having a first lateral surface;
a first insulation body disposed between the first semiconductor device and the second semiconductor device and having a first lateral surface; and
a second insulation body encapsulating the first insulation body,
wherein the first lateral surface of the first insulation body is substantially coplanar with the first lateral surface of the second semiconductor device.

14. The semiconductor device package of claim 13, wherein the second semiconductor device has a width greater than the first semiconductor device.

15. The semiconductor device package of claim 13, wherein the first lateral surface of the first insulation body is substantially coplanar with the first lateral surface of the first semiconductor device.

16. The semiconductor device package of claim 13, wherein the first insulation body has a number of first particles, and the second insulation body has a number of second particles, and wherein one of the number of first particles has a flat surface

17. The semiconductor device package of claim 13, wherein a portion of the second insulation body is disposed between the redistribution layer and the first semiconductor device.

18. The semiconductor device package of claim 13, wherein the first insulation body has an indentation.

19. The semiconductor device package of claim 13, wherein the second insulation body has a convex surface engaged with the concave surface of the first insulation body.

20. A method of manufacturing a semiconductor device package, comprising:
providing a wafer including a number of first semiconductor devices;
forming a number of stacks of second semiconductor devices on the wafer; and
encapsulating the number of stacks of second semiconductor devices and the wafer by a first insulation material.

21. The method of claim 20, further comprising separating the encapsulated stacks of second semiconductor devices and the wafer.

22. The method of claim 21, further comprising encapsulating the separated, encapsulated stacks of second semiconductor devices and the wafer by a second insulation material.

23. The semiconductor device package of claim 16, wherein the flat surface of the one of the number of first particles is in direct contact with the second insulation body.

24. The semiconductor device package of claim 16, wherein an average size of the number of first particles is substantially less than the number of second particles and a ratio of a maxima size to a minimum size with respect to the first particles is substantially less than a ratio of a maxima size to a minimum size with respect to the second particles.

25. The semiconductor device package of claim 16, wherein an average content of the first particles is substantially greater than an average content of the second particles.
